(19) United States
(12) Patent Application Publication
(10) Pub. No.: US 2024/0160102 A1
(43) Pub. Date: May 16, 2024

(54) POSITIVE RESIST COMPOSITION AND METHOD OF FORMING RESIST PATTERN

(71) Applicant: ZEON CORPORATION, Chiyoda-ku, Tokyo (JP)

(72) Inventor: Manabu HOSHINO, Chiyoda-ku, Tokyo (JP)

(73) Assignee: ZEON CORPORATION, Chiyoda-ku, Tokyo (JP)

(21) Appl. No.: 18/546,430

(22) PCT Filed: Feb. 1, 2022
(86) PCT No.: PCT/JP2022/003873

§ 371 Date: Aug. 15, 2023

(30) Foreign Application Priority Data
Mar. 9, 2021 (JP) 2021-037813
Aug. 25, 2021 (JP) 2021-137531

(51) Int. Cl. G03F 7/039; C08F 212/08; C08F 220/24

(52) U.S. Cl. CPC G03F 7/039; C08F 212/08; C08F 220/24

(57) ABSTRACT

Provided is a technique that enables formation of a resist pattern having little resist pattern top loss and high contrast. A positive resist composition that contains a copolymer A, a copolymer B, and a solvent and in which a difference between surface free energy of the copolymer A and surface free energy of the copolymer B is 4 mJ/m² or more is used as a positive resist composition.

### TECHNICAL FIELD

The present disclosure relates to a positive resist composition and a method of forming a resist pattern.

### BACKGROUND

Polymers that display increased solubility in a developer after undergoing main chain scission through irradiation with ionizing radiation, such as an electron beam, or short-wavelength light, such as ultraviolet light, are conventionally used as main chain scission-type positive resists in fields such as semiconductor production. (Hereinafter, the term “ionizing radiation or the like” is used to refer collectively to ionizing radiation and short-wavelength light.)

For example, PTL 1 discloses a positive resist composition containing, as a main chain scission-type positive resist having excellent sensitivity to ionizing radiation or the like and heat resistance, a positive resist that is formed of a copolymer including a 1-phenyl-1-trifluoromethyl-2,2,2-trifluoroethyl α-chloroacrylate unit and an α-methylstyrene unit.

### CITATION LIST

### Patent Literature

PTL 1: JP2018-154754A

### SUMMARY

### Technical Problem

However, there is room for improvement of a resist pattern formed using the conventional positive resist composition described above in terms of reducing loss of the top of the resist pattern (top loss) and in terms of increasing the contrast of the resist pattern.

Accordingly, one object of the present disclosure is to provide a positive resist composition that is capable of forming a resist pattern having little resist pattern top loss and high contrast.

Another object of the present disclosure is to provide a method of forming a resist pattern that is capable of forming a resist pattern having little resist pattern top loss and high contrast.

### Solution to Problem

The inventor conducted diligent studies with the aim of achieving the objects set forth above. The inventor made a new discovery that a resist pattern having little resist pattern top loss and high contrast can be formed by using a positive resist composition that contains two specific types of copolymers as a positive resist, and, in this manner, completed the present disclosure.

Specifically, the present disclosure aims to advantageously solve the problem set forth above, and a presently disclosed positive resist composition comprises: a copolymer A; a copolymer B; and a solvent, wherein a difference between surface free energy of the copolymer A and surface free energy of the copolymer B is 4 mJ/m² or more. By using a positive resist composition that contains a copolymer A, a copolymer B, and a solvent and in which the difference between surface free energy of the copolymer A and surface free energy of the copolymer B is 4 mJ/m² or more in this manner, it is possible to form a resist pattern having little resist pattern top loss and high contrast.

Note that the “surface free energy” referred to in the present disclosure can be measured by a method described in the EXAMPLES section of the present specification.

In the presently disclosed positive resist composition, at least one of the copolymer A and the copolymer B is preferably a main chain scission-type copolymer that includes a halogen atom. More preferably, at least one of the copolymer A and the copolymer B includes a fluorine substituent, at least one of the halogen atom is a fluorine atom, and the fluorine atom is included in the fluorine substituent.

When at least one of the copolymer A and the copolymer B is a main chain scission-type copolymer that includes a halogen atom, and preferably when at least one of the copolymer A and the copolymer B includes a fluorine substituent, at least one of the aforementioned halogen atom is a fluorine atom, and this fluorine atom is included in the fluorine substituent, it is possible to form a resist pattern having even less resist pattern top loss and even higher contrast.

Note that when a copolymer is referred to as a “main chain scission-type” in the present disclosure, this means that the copolymer has a property of undergoing scission of a main chain thereof in a situation in which the copolymer is irradiated with ionizing radiation or the like such as an electron beam or extreme ultraviolet light (EUV).

The presently disclosed positive resist composition preferably does not substantially comprise a component having a weight-average molecular weight (Mw) of less than 1,000. When the positive resist composition does not substantially contain a component having a weight-average molecular weight (Mw) of less than 1,000, the contrast of a resist pattern can be even further increased.

Note that the “weight-average molecular weight” referred to in the present disclosure can be measured as a standard polystyrene-equivalent value by gel permeation chromatography.

Also note that the phrase “does not substantially comprise” as used in the present disclosure means that a component is not actively compounded and that “actively compounded” is exclusive of a case in which mixing in of a component is unavoidable. More specifically, this indicates that the proportional content of a component having a weight-average molecular weight (Mw) of less than 1,000 in the positive resist composition is less than 0.05 mass %.

In the presently disclosed positive resist composition, at least one of the copolymer A and the copolymer B preferably includes a monomer unit (V) represented by formula (V), shown below,

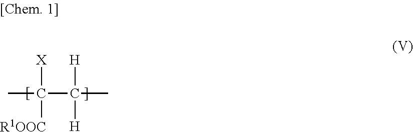

where, in formula (V), X is a halogen atom, a cyano group, an alkylsulfonyl group, an alkoxy group, a nitro group, an acyl group, an alkyl ester group, or a haloalkyl group, and R¹ is an organic group including not fewer than 3 and not more than 10 fluorine atoms. When at least one of the copolymer A and the copolymer B includes the monomer unit (V), the contrast of a resist pattern can be even further increased.

In the presently disclosed positive resist composition, the copolymer A preferably includes: a monomer unit (I) represented by formula (I), shown below,

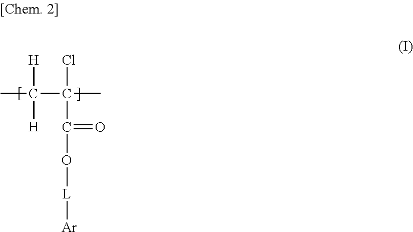

where, in formula (I), L is a divalent linking group that includes a fluorine atom, and Ar is an optionally substituted aromatic ring group; and a monomer unit (II) represented by formula (II), shown below,

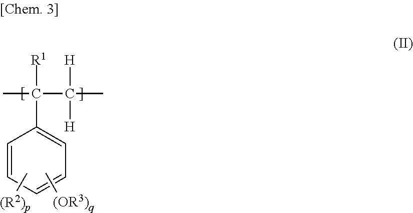

where, in formula (II), R¹ is an alkyl group, R² is a hydrogen atom, an alkyl group, a halogen atom, a haloalkyl group, a hydroxyl group, a carboxyl group, or a halogenated carboxyl group, R³ is a hydrogen atom, an unsubstituted alkyl group, or a fluorine atom-substituted alkyl group, p and q are integers of not less than 0 and not more than 5, and p+q=5. By using a copolymer A that includes the monomer unit (I) and the monomer unit (II), it is possible to even further increase the contrast of a resist pattern.

Note that the term “optionally substituted” as used in the present disclosure means “unsubstituted or having one or more substituents”.

In the presently disclosed positive resist composition, the copolymer B preferably includes: a monomer unit (III) represented by formula (III), shown below,

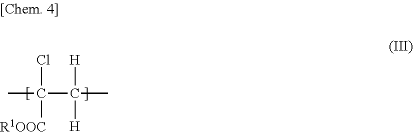

where, in formula (III), R¹ is an organic group including not fewer than 5 and not more than 7 fluorine atoms; and a monomer unit (IV) represented by formula (IV), shown below,

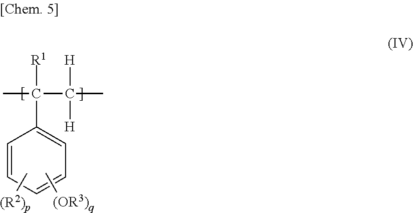

where, in formula (IV), R¹ is an alkyl group, R² is a hydrogen atom, a fluorine atom, an unsubstituted alkyl group, or a fluorine atom-substituted alkyl group, R³ is a hydrogen atom, an unsubstituted alkyl group, or a fluorine atom -substituted alkyl group, p and q are integers of not less than 0 and not more than 5, and p+q=5. By using a copolymer B that includes the monomer unit (III) and the monomer unit (IV), it is possible to even further increase the contrast of a resist pattern.

Moreover, the present disclosure aims to advantageously solve the problem set forth above, and a presently disclosed method of forming a resist pattern comprises: forming a resist film using any one of the positive resist compositions set forth above; exposing the resist film; and developing the resist film that has been exposed. By forming a resist film using the presently disclosed positive resist composition, exposing the obtained resist film, and subsequently developing the exposed resist film in this manner, it is possible to form a resist pattern having little resist pattern top loss and high contrast. In the presently disclosed method of forming a resist pattern, the

developing is preferably performed using an alcohol. By performing the developing using an alcohol, it is possible to even further increase the contrast of a resist pattern.

### Advantageous Effect

According to the present disclosure, it is possible to provide a positive resist composition that is capable of forming a resist pattern having little resist pattern top loss and high contrast.

Moreover, according to the present disclosure, it is possible to provide a method of forming a resist pattern that is capable of forming a resist pattern having little resist pattern top loss and high contrast.

### DETAILED DESCRIPTION

The following provides a detailed description of embodiments of the present disclosure.

The presently disclosed positive resist composition is used to form a resist film in the formation of a resist pattern using ionizing radiation or the like such as an electron beam or EUV. The presently disclosed method of forming a resist pattern is a method of forming a resist pattern using the presently disclosed positive resist composition. The presently disclosed method of forming a resist pattern can be used in formation of a resist pattern in a production process of a semiconductor, a photomask, or a mold, for example, without any specific limitations.

### Positive Resist Composition

The presently disclosed positive resist composition contains a copolymer A, a copolymer B, and a solvent that are described below in detail and optionally further contains known additives that can be compounded in positive resist compositions.

The presently disclosed positive resist composition is required to contain the copolymer A and the copolymer B, and a difference between the surface free energy of the copolymer A and the surface free energy of the copolymer B is required to be 4 mJ/m² or more. As a result of the presently disclosed positive resist composition containing the copolymer A and the copolymer B that have a surface free energy difference of 4 mJ/m² or more as a positive resist, it is possible to reduce resist pattern top loss and form a resist pattern having high contrast by using this positive resist composition.

The presently disclosed positive resist composition preferably does not substantially contain a component having a weight-average molecular weight (Mw) of less than 1,000. More specifically, the proportional content of a component having a weight-average molecular weight (Mw) of less than 1,000 in the positive resist composition is less than 0.05 mass %, preferably less than 0.01 mass %, and more preferably less than 0.001 mass %.

### <Copolymer A>

The copolymer A contained in the presently disclosed positive resist composition is not specifically limited so long as the difference between the surface free energy of the copolymer A and the surface free energy of the copolymer B is 4 mJ/m² or more. In terms of enabling formation of a resist pattern having even less resist pattern top loss and even higher contrast, it is preferable that the copolymer A is a main chain scission-type copolymer that includes a halogen atom, and more preferable that the copolymer A includes a fluorine substituent, that at least one of the aforementioned halogen atom is a fluorine atom, and that this fluorine atom is included in the fluorine substituent.

The fluorine substituent is not specifically limited so long as it is a substituent that includes a fluorine atom.

### {Surface Free Energy of the Copolymer A}

The surface free energy of the copolymer A is preferably 28 mJ/m² or more, more preferably 29 mJ/m² or more, and even more preferably 30 mJ/m² or more, and is preferably 35 mJ/m² or less, more preferably 34 mJ/m² or less, and even more preferably 33 mJ/m² or less.

From a viewpoint of further increasing the contrast of a resist pattern, the copolymer A that is contained in the presently disclosed positive resist composition preferably includes a monomer unit (V) represented by the following formula (V).

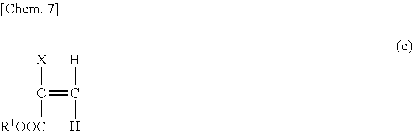

(In formula (V), X is a halogen atom, a cyano group, an alkylsulfonyl group, an alkoxy group, a nitro group, an acyl group, an alkyl ester group, or a haloalkyl group, and R¹ is an organic group including not fewer than 3 and not more than 10 fluorine atoms.)

The monomer unit (V) is a structural unit that is derived from a monomer (e) represented by the following formula (e).

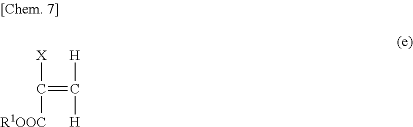

(In formula (e), X and R¹ are the same as in formula (V).)

The proportion constituted by the monomer unit (e) among all monomer units of the copolymer A can be set as 30 mol % or more, preferably 40 mol % or more, and more preferably 45 mol % or more, and can be set as 70 mol % or less, preferably 60 mol % or less, and more preferably 55 mol % or less, for example, without any specific limitations.

The halogen atom that can constitute X in formulae (V) and (e) may be a chlorine atom, a fluorine atom, a bromine atom, an iodine atom, an astatine atom, or the like, for example. The alkylsulfonyl group that can constitute X in formulae (V) and (e) may be a methylsulfonyl group, an ethylsulfonyl group, or the like, for example. The alkoxy group that can constitute X in formulae (V) and (e) may be a methoxy group, an ethoxy group, a propoxy group, or the like, for example. The acyl group that can constitute X in formulae (V) and (e) may be a formyl group, an acetyl group, a propionyl group, or the like. The alkyl ester group that can constitute X in formulae (V) and (e) may be a methyl ester group, an ethyl ester group, or the like. The haloalkyl group that can constitute X in formulae (V) and (e) may be a halomethyl group including not fewer than 1 and not more than 3 fluorine atoms, or the like, for example.

In particular, X is preferably a halogen atom, and more preferably a chlorine atom.

R¹ in formulae (V) and (e) is an organic group including not fewer than 3 and not more than 10 fluorine atoms. The number of fluorine atoms included in RI is preferably not less than 5 and not more than 7. When the number of fluorine atoms included in RI is not less than any of the lower limits set forth above, the copolymer A is useful as a main chain scission-type positive resist. Moreover, when the number of fluorine atoms included in RI is not more than any of the upper limits set forth above, production efficiency of the copolymer A is excellent.

The organic group including not fewer than 3 and not more than 10 fluorine atoms (preferably not fewer than 5 and not more than 7) may be a fluoroalkyl group including not fewer than 3 and not more than 10 fluorine atoms such as (a-1) to (a-30), shown below; a fluoroalkoxyalkyl group including not fewer than 3 and not more than 10 fluorine atoms such as (a-31) to (a-54), shown below; a fluoroalkoxyalkenyl group including not fewer than 3 and not more than 10 fluorine atoms such as a fluoroethoxyvinyl group; an organic group (hereinafter, referred to as “organic group (A)”) represented by formula (A), shown below; or the like, for example, without any specific limitations.

-L-Ar (A)

(In the organic group (A), L is a divalent linking group, Ar is an optionally substituted aromatic ring group, and the number of fluorine atoms included in the organic group (A) is not less than 3 and not more than 10 (preferably not less than 5 and not more than 7).)

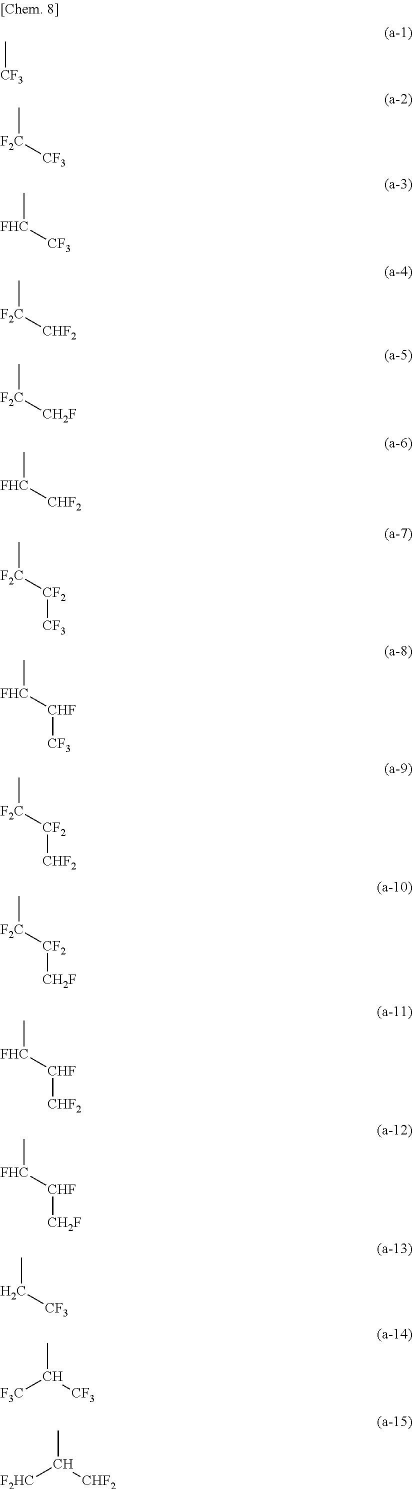

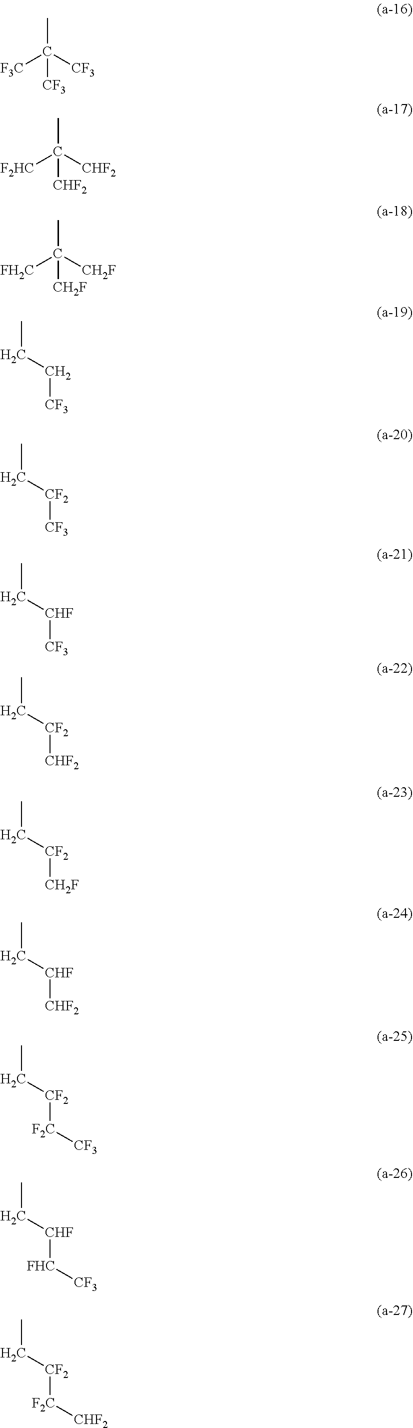

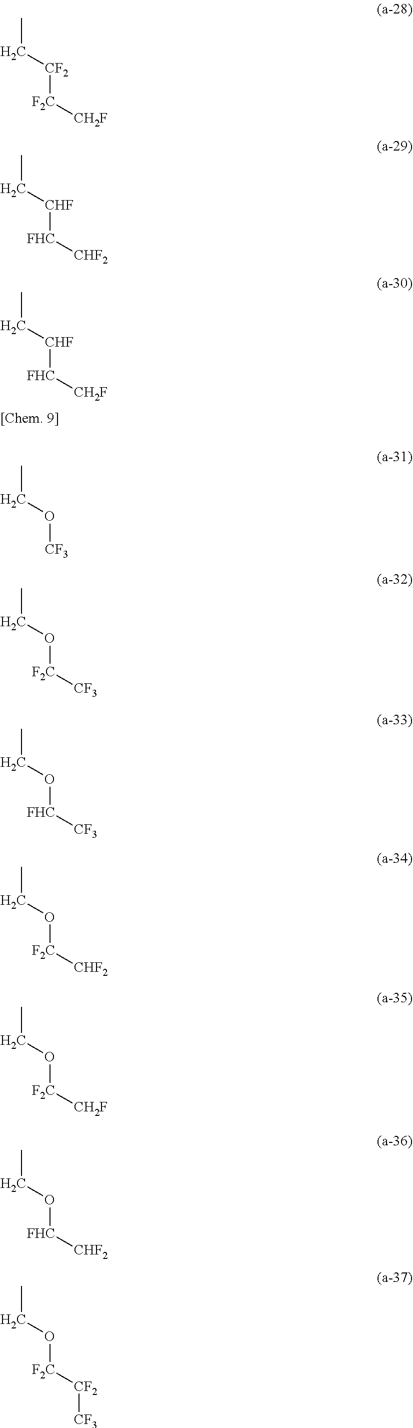

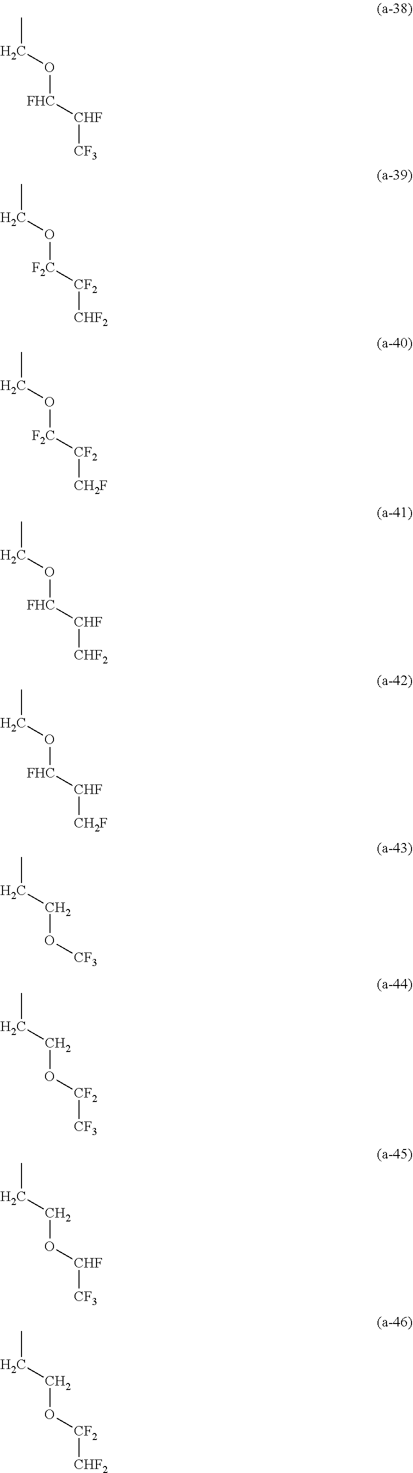

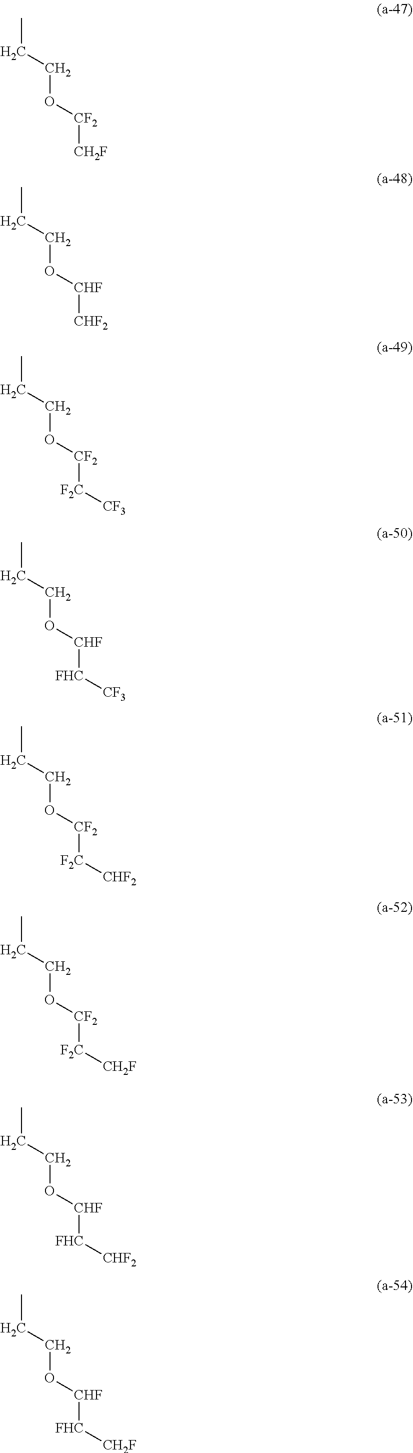

The divalent linking group that can constitute L in the organic group (A) may be an optionally substituted alkylene group, an optionally substituted alkenylene group, or the like, for example, without any specific limitations.

The alkylene group of the optionally substituted alkylene group may be a chain alkylene group such as a methylene group, an ethylene group, a propylene group, an n-butylene group, or an isobutylene group or a cyclic alkylene group such as a 1,4-cyclohexylene group, for example, without any specific limitations. Of these examples, a chain alkylene group having a carbon number of 1 to 6 such as a methylene group, an ethylene group, a propylene group, an n-butylene group, or an isobutylene group is preferable as the alkylene group, a linear alkylene group having a carbon number of 1 to 6 such as a methylene group, an ethylene group, a propylene group, or an n-butylene group is more preferable as the alkylene group, and a linear alkylene group having a carbon number of 1 to 3 such as a methylene group, an ethylene group, or a propylene group is even more preferable as the alkylene group.

The alkenylene group of the optionally substituted alkenylene group may be a chain alkenylene group such as an ethenylene group, a 2-propenylene group, a 2-butenylene group, or a 3-butenylene group or a cyclic alkenylene group such as a cyclohexenylene group, for example, without any specific limitations. Of these examples, a linear alkenylene group having a carbon number of 2 to 6 such as an ethenylene group, a 2-propenylene group, a 2-butenylene group, or a 3-butenylene group is preferable as the alkenylene group.

Of the examples described above, an optionally substituted alkylene group is preferable as the divalent linking group from a viewpoint of sufficiently improving sensitivity to ionizing radiation or the like of the obtained copolymer A, with an optionally substituted chain alkylene group having a carbon number of 1 to 6 being more preferable, an optionally substituted linear alkylene group having a carbon number of 1 to 6 being even more preferable, and an optionally substituted linear alkylene group having a carbon number of 1 to 3 being particularly preferable.

Moreover, from a viewpoint of further improving sensitivity to ionizing radiation or the like of the copolymer A, the divalent linking group that can constitute L of the organic group (A) preferably includes one or more electron withdrawing groups. In particular, in a case in which the divalent linking group is an alkylene group that includes an electron withdrawing group as a substituent or an alkenylene group that includes an electron withdrawing group as a substituent, the electron withdrawing group is preferably bonded to a carbon that is bonded to the oxygen adjacent to the carbonyl carbon in formula (V).

Note that one or more selected from the group consisting of a fluorine atom, a fluoroalkyl group, a cyano group, and a nitro group may, for example, serve as an electron withdrawing group that can sufficiently improve sensitivity to ionizing radiation or the like without any specific limitations. The fluoroalkyl group may be a fluoroalkyl group having a carbon number of 1 to 5, for example, without any specific limitations. In particular, the fluoroalkyl group is preferably a perfluoroalkyl group having a carbon number of 1 to 5, and more preferably a trifluoromethyl group.

From a viewpoint of further increasing producibility of the copolymer A, L in the organic group (A) is preferably a divalent linking group including not fewer than 3 and not more than 10 fluorine atoms, more preferably a divalent linking group including not fewer than 3 and not more than 6 fluorine atoms, and even more preferably a trifluoromethylmethylene group, a pentafluoroethylmethylene group, or a bis(trifluoromethyl)methylene group.

Ar in the organic group (A) may be an optionally substituted aromatic hydrocarbon ring group or an optionally substituted aromatic heterocyclic group.

The aromatic hydrocarbon ring group may be a benzene ring group, a biphenyl ring group, a naphthalene ring group, an azulene ring group, an anthracene ring group, a phenanthrene ring group, a pyrene ring group, a chrysene ring group, a naphthacene ring group, a triphenylene ring group, an o-terphenyl ring group, an m-terphenyl ring group, a p-terphenyl ring group, an acenaphthene ring group, a coronene ring group, a fluorene ring group, a fluoranthene ring group, a pentacene ring group, a perylene ring group, a pentaphene ring group, a picene ring group, a pyranthrene ring group, or the like, for example, without any specific limitations.

The aromatic heterocyclic group may be a furan ring group, a thiophene ring group, a pyridine ring group, a pyridazine ring group, a pyrimidine ring group, a pyrazine ring group, a triazine ring group, an oxadiazole ring group, a triazole ring group, an imidazole ring group, a pyrazole ring group, a thiazole ring group, an indole ring group, a benzimidazole ring group, a benzothiazole ring group, a benzoxazole ring group, a quinoxaline ring group, a quinazoline ring group, a phthalazine ring group, a benzofuran ring group, a dibenzofuran ring group, a benzothiophene ring group, a dibenzothiophene ring group, a carbazole ring group, or the like, for example, without any specific limitations.

Examples of possible substituents of Ar include an alkyl group, a fluorine atom, and a fluoroalkyl group without any specific limitations. Examples of alkyl groups that are possible substituents of Ar include chain alkyl groups having a carbon number of 1 to 6 such as a methyl group, an ethyl group, a propyl group, an n-butyl group, and an isobutyl group. Examples of fluoroalkyl groups that are possible substituents of Ar include fluoroalkyl groups having a carbon number of 1 to 5 such as a trifluoromethyl group, a trifluoroethyl group, and a pentafluoropropyl group.

Of these examples, an optionally substituted aromatic hydrocarbon ring group is preferable as Ar in the organic group (A) from a viewpoint of increasing ease of production of the copolymer A, with an unsubstituted aromatic hydrocarbon ring group being more preferable, and a benzene ring group (phenyl group) being even more preferable.

The monomer (e) represented by formula (e) may be an α-chloroacrylic acid fluoroalkyl ester such as 2,2,2-trifluoroethyl α-chloroacrylate, 2,2,3,3,3-pentafluoropropyl α-chloroacrylate, 3,3,4,4,4-pentafluorobutyl chloroacrylate, 1H-1-(trifluoromethyl)trifluoroethyl α-chloroacrylate, 1H, 1H,3H-hexafluorobutyl α-chloroacrylate, 1,2,2,2-tetrafluoro-1-(trifluoromethyl)ethyl α-chloroacrylate, or 2,2,3,3,4,4,4-heptafluorobutyl α-chloroacrylate; an α-chloroacrylic acid fluoroalkoxyalkyl ester such as pentafluoroethoxymethyl α-chloroacrylate or pentafluoroethoxyethyl α-chloroacrylate; an α-chloroacrylic acid fluoroalkoxyalkenyl ester such as pentafluoroethoxyvinyl α-chloroacrylate; 1-phenyl-1-trifluoromethyl-2,2,2-trifluoroethyl α-chloroacrylate, 1-phenyl-2,2,2-trifluoroethyl α-chloroacrylate, 1-phenyl-2,2,3,3,3-pentafluoropropyl α-chloroacrylate, or the like, for example, without any specific limitations. From a viewpoint of further increasing production efficiency of the copolymer A, the monomer (e) represented by formula (e) is preferably 1-phenyl-1-trifluoromethyl-2,2,2-trifluoroethyl α-chloroacrylate, 1-phenyl-2,2,2-trifluoroethyl α-chloroacrylate, or 1-phenyl-2,2,3,3,3-pentafluoropropyl α-chloroacrylate, and is more preferably 1-phenyl-1-trifluoromethyl-2,2,2-trifluoroethyl α-chloroacrylate or 1-phenyl-2,2,3,3,3-pentafluoropropyl α-chloroacrylate.

From a viewpoint of even further increasing the contrast of a resist pattern, the copolymer A that is contained in the presently disclosed positive resist composition preferably includes: a monomer unit (I) represented by formula (I), shown below,

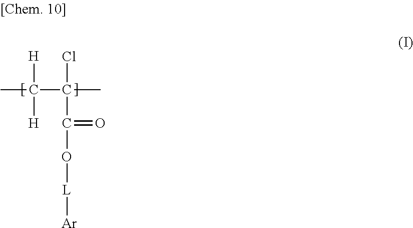

(in formula (I), L is a divalent linking group that includes a fluorine atom, and Ar is an optionally substituted aromatic group); and a monomer unit (II) represented by formula (II), shown below,

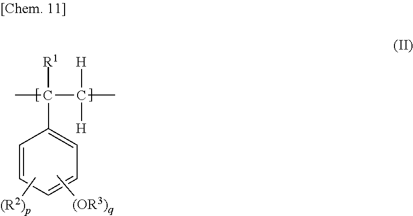

(in formula (II), R¹ is an alkyl group, R² is a hydrogen atom, an alkyl group, a halogen atom, a haloalkyl group, a hydroxyl group, a carboxyl group, or a halogenated carboxyl group, R³ is a hydrogen atom, an unsubstituted alkyl group, or a fluorine atom-substituted alkyl group, p and q are integers of not less than 0 and not more than 5, and p+q=5). Note that although the copolymer A may also include any monomer

units other than the monomer unit (I) and the monomer unit (II), the proportion constituted by the monomer unit (I) and the monomer unit (II) among all monomer units of the copolymer A is, in total, preferably 90 mol % or more, and more preferably 100 mol % (i.e., the copolymer A more preferably only includes the monomer unit (I) and the monomer unit (II)).

The copolymer A undergoes efficient main chain scission to lower molecular weight upon irradiation with an electron beam or the like as a result of including the monomer unit (I) and the monomer unit (II).

The monomer unit (I) is a structural unit that is derived from a monomer (a) represented by the following formula (a).

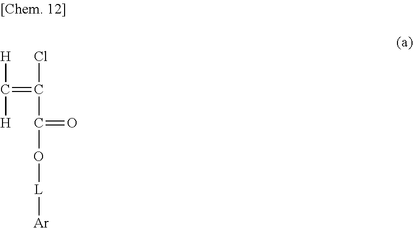

(In formula (a), L and Ar are the same as in formula (I).)

The divalent linking group including a fluorine atom that can constitute L in formula (I) and formula (a) may be a divalent chain alkyl group having a carbon number of 1 to 5 that includes a fluorine atom or the like, for example. The number of fluorine atoms is not less than 3 and not more than 10, and more preferably not less than 5 and not more than 7.

The optionally substituted aromatic ring group that can constitute Ar in formula (I) and formula (a) may be an optionally substituted aromatic hydrocarbon ring group or an optionally substituted aromatic heterocyclic group.

The aromatic hydrocarbon ring group may be any of the same groups as for the aromatic hydrocarbon ring group that can constitute Ar in the above-described formulae (V) and (e), for example, without any specific limitations.

The aromatic heterocyclic group may be any of the same groups as for the aromatic heterocyclic group that can constitute Ar in the above-described formulae (V) and (e), for example, without any specific limitations.

Examples of possible substituents of Ar include the same groups as the possible substituents of Ar in the above-described formulae (V) and (e), for example, without any specific limitations.

Of these examples, an optionally substituted aromatic hydrocarbon ring group is preferable as Ar in formula (I) and formula (a) from a viewpoint of sufficiently improving sensitivity to an electron beam or the like, with an unsubstituted aromatic hydrocarbon ring group being more preferable, and a benzene ring group (phenyl group) being even more preferable.

From a viewpoint of sufficiently improving sensitivity to an electron beam or the like, 1-phenyl-1-trifluoromethyl-2,2,2-trifluoroethyl α-chloroacrylate (ACAFPh) and 1-(4-methoxyphenyl)-1-trifluoromethyl-2,2,2-trifluoroethyl α-chloroacrylate (ACAFPhOMe) are preferable as the monomer (a) represented by the above-described formula (a) that can form the monomer unit (I) represented by the above-described formula (I), and 1-phenyl-1-trifluoromethyl-2,2,2-trifluoroethyl α-chloroacrylate is more preferable as the monomer (a). In other words, the copolymer A preferably includes either or both of a 1-phenyl-1-trifluoromethyl-2,2,2-trifluoroethyl α-chloroacrylate unit and a 1-(4-methoxyphenyl)-1-trifluoromethyl-2,2,2-trifluoroethyl α-chloroacrylate unit, and more preferably includes a 1-phenyl-1 -trifluoromethyl-2,2,2-trifluoroethyl α-chloroacrylate unit.

The proportion constituted by the monomer unit (I) among all monomer

units of the copolymer A can be set as 30 mol % or more, preferably 40 mol % or more, and more preferably 45 mol % or more, and can be set as 70 mol % or less, preferably 60 mol % or less, and more preferably 55 mol % or less, for example, without any specific limitations.

The monomer unit (II) is a structural unit that is derived from a monomer (b) represented by the following formula (b).

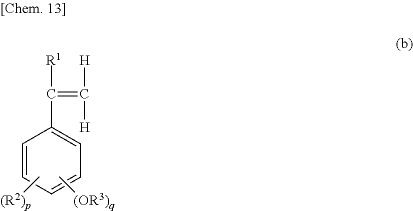

(In formula (b), R¹, R², p, and q are the same as in formula (II).)

The alkyl group that can constitute R¹ and R² in formula (II) and formula (b) may be an unsubstituted alkyl group having a carbon number of 1 to 5, for example, without any specific limitations. In particular, a methyl group or an ethyl group is preferable as the alkyl group that can constitute R¹ and R².

The halogen atom that can constitute R² in formula (II) and formula (b) may be a fluorine atom, a chlorine atom, a bromine atom, an iodine atom, or the like, without any specific limitations. Of these examples, a fluorine atom is preferable as the halogen atom.

The haloalkyl group that can constitute R² in formula (II) and formula (b) may be a fluoroalkyl group having a carbon number of 1 to 5, for example, without any specific limitations. In particular, a perfluoroalkyl group having a carbon number of 1 to 5 is preferable as the haloalkyl group, and a trifluoromethyl group is more preferable as the haloalkyl group.

The halogenated carboxyl group that can constitute R² in formula (II) and formula (b) may be a chlorinated carboxyl group (—C(═O)—Cl), a fluorinated carboxyl group (—C(═O)—F), a brominated carboxyl group (—C(═O)—Br), or the like, for example, without any specific limitations.

From a viewpoint of improving ease of production of the copolymer A and main chain scission properties of the copolymer A upon irradiation with an electron beam or the like, R¹ in formula (II) and formula (b) is preferably an alkyl group having a carbon number of 1 to 5, and more preferably a methyl group.

Moreover, from a viewpoint of improving ease of production of the copolymer A and main chain scission properties of the copolymer A upon irradiation with an electron beam or the like, p in formula (II) and formula (b) is preferably 0 or 1.

Furthermore, in a case in which p in formula (II) and formula (b) is any one of 1 to 5, R² in formula (II) and formula (b) is preferably an alkyl group having a carbon number of 1 to 5, and more preferably a methyl group.

The unsubstituted alkyl group that can constitute R³ in formulae (II) and (b) may be an unsubstituted alkyl group having a carbon number of not less than 1 and not more than 5 without any specific limitations. In particular, the unsubstituted alkyl group that can constitute R³ is preferably a methyl group or an ethyl group.

The fluorine atom-substituted alkyl group that can constitute R³ in formulae (II) and (b) may be a group having a structure in which some or all of the hydrogen atoms in an alkyl group have been replaced with fluorine atoms.

The monomer (b) represented by the above-described formula (b) that can form the monomer unit (II) represented by the above-described formula (II) may be α-methylstyrene (AMS) or a derivative thereof, such as the following monomers (b-1) to (b-12), for example, without any specific limitations.

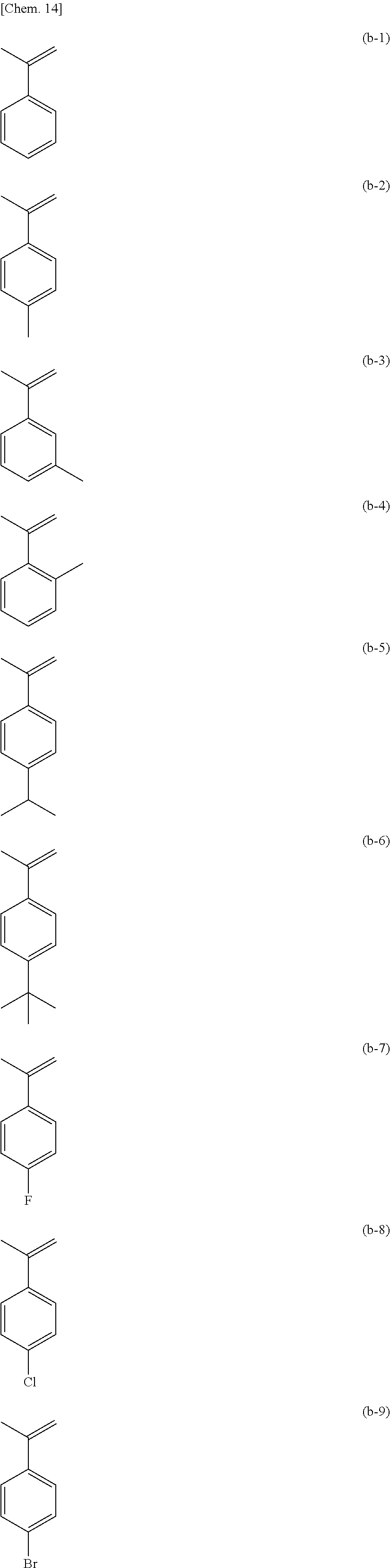

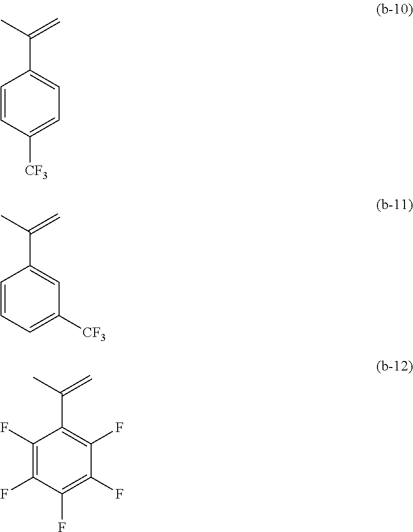

From a viewpoint of improving ease of production of the copolymer A and main chain scission properties of the copolymer A upon irradiation with an electron beam or the like, α-methylstyrene is preferable as the monomer (b) represented by the above-described formula (b) that can form the monomer unit (II). In other words, the copolymer A preferably includes an α-methylstyrene unit.

The proportion constituted by the monomer unit (II) among all monomer units of the copolymer A can be set as 30 mol % or more, preferably 40 mol % or more, and more preferably 45 mol % or more, and can be set as 70 mol % or less, preferably 60 mol % or less, and more preferably 55 mol % or less, for example, without any specific limitations.

### <Properties of Copolymer A>

### [Weight-Average Molecular Weight (Mw)]

The weight-average molecular weight (Mw) of the copolymer A is preferably 100,000 or more, more preferably 125,000 or more, and even more preferably 150,000 or more, and is preferably 600,000 or less, and more preferably 500,000 or less. When the weight-average molecular weight (Mw) of the copolymer A is not less than any of the lower limits set forth above, resist pattern top loss can be further reduced, and a resist pattern having further improved contrast can be formed. Moreover, when the weight-average molecular weight (Mw) of the copolymer A is not more than any of the upper limits set forth above, adjustment of the positive resist composition can be facilitated.

### [Number-Average Molecular Weight (Mn)]

The number-average molecular weight (Mn) of the copolymer A is preferably 100,000 or more, and more preferably 110,000 or more, and is preferably 300,000 or less, and more preferably 200,000 or less. When the number-average molecular weight of the copolymer A is not less than any of the lower limits set forth above, resist pattern top loss can be even further reduced, and a resist pattern having even further improved contrast can be formed. Moreover, when the number-average molecular weight of the copolymer A is not more than any of the upper limits set forth above, the positive resist composition is even easier to produce.

### [Molecular Weight Distribution (Mw/Mn)]

The molecular weight distribution (Mw/Mn) of the copolymer A is preferably 1.20 or more, more preferably 1.25 or more, and even more preferably 1.30 or more, and is preferably 2.00 or less, more preferably 1.80 or less, and even more preferably 1.60 or less.

Note that the “number-average molecular weight” referred to in the present disclosure can be measured as a standard polystyrene-equivalent value by gel permeation chromatography, and that the “molecular weight distribution” referred to in the present disclosure can be determined by calculating a ratio of the weight-average molecular weight relative to the number-average molecular weight (weight-average molecular weight/number-average molecular weight).

### [Production Method of Copolymer A]

No specific limitations are placed on the method by which the copolymer A is produced. For example, a copolymer A that includes the previously described monomer unit (V) can be produced by carrying out polymerization of a monomer composition that contains the monomer (e) and any monomer that is copolymerizable with the monomer (e), and then collecting and optionally purifying the resultant copolymer.

The chemical composition, molecular weight distribution, number-average molecular weight, and weight-average molecular weight of the copolymer A can be adjusted by altering the polymerization conditions and the purification conditions. In one specific example, the number-average molecular weight and the weight-average molecular weight can be increased by lowering the polymerization temperature. Moreover, the number-average molecular weight and the weight-average molecular weight can be increased by shortening the polymerization time. Furthermore, the molecular weight distribution can be reduced by performing purification.

### <Polymerization of Monomer Composition>

The monomer composition used in production of the copolymer A may be a mixture containing a monomer component that includes the monomer (e) and any monomer copolymerizable with the monomer (e), an optionally used solvent, an optionally used polymerization initiator, and optionally added additives, for example. Polymerization of the monomer composition may be carried out by a known method. In particular, it is preferable that cyclopentanone, water, or the like is used as the solvent.

A polymerized product obtained through polymerization of the monomer composition may, without any specific limitations, be collected by adding a good solvent such as tetrahydrofuran to a solution containing the polymerized product and subsequently dripping the solution to which the good solvent has been added into a poor solvent such as methanol, ethanol, 1-propanol, 1-butanol, 1-pentanol, or hexane to cause coagulation of the polymerized product.

### <Purification of Polymerized Product>

The method of purification in a case in which the obtained polymerized product is purified may be a known purification method such as reprecipitation or column chromatography without any specific limitations. Of these purification methods, purification by reprecipitation is preferable.

Note that purification of the polymerized product may be performed repeatedly.

Purification of the polymerized product by reprecipitation is, for example, preferably carried out by dissolving the obtained polymerized product in a good solvent such as tetrahydrofuran, and subsequently dripping the resultant solution into a mixed solvent of a good solvent, such as tetrahydrofuran, and a poor solvent, such as methanol, ethanol, 1-propanol, 1-butanol, 1-pentanol, or hexane, to cause precipitation of a portion of the polymerized product. When purification is carried out by dripping a solution of the polymerized product into a mixed solvent of a good solvent and a poor solvent in this manner, the molecular weight distribution, number-average molecular weight, and weight-average molecular weight of the resultant copolymer A can easily be adjusted by altering the types and/or mixing ratio of the good solvent and the poor solvent. In one specific example, the molecular weight of copolymer that precipitates in the mixed solvent can be increased by increasing the proportion of the good solvent in the mixed solvent.

Also note that in a situation in which the polymerized product is purified by reprecipitation, polymerized product that precipitates in the mixed solvent of the good solvent and the poor solvent may be used as the copolymer A, or polymerized product that does not precipitate in the mixed solvent (i.e., polymerized product dissolved in the mixed solvent) may be used as the copolymer A, so long as the polymerized product that is used satisfies the desired properties. Polymerized product that does not precipitate in the mixed solvent can be collected from the mixed solvent by a known technique such as concentration to dryness.

### <Copolymer B>

The copolymer B contained in the presently disclosed positive resist composition is not specifically limited so long as the difference between the surface free energy of the copolymer B and the surface free energy of the copolymer A is 4 mJ/m² or more. In terms of enabling formation of a resist pattern having even less resist pattern top loss and even higher contrast, it is preferable that the copolymer B is a main chain scission-type copolymer that includes a halogen atom, and more preferable that the copolymer B includes a fluorine substituent, that at least one of the aforementioned halogen atom is a fluorine atom, and that this fluorine atom is included in the fluorine substituent. The fluorine substituent is not specifically limited so long as it is a substituent that includes a fluorine atom.

### {Surface Free Energy of the Copolymer B}

The surface free energy of the copolymer B is preferably 18 mJ/m² or more, more preferably 19 mJ/m² or more, and even more preferably 20 mJ/m² or more, and is preferably 27 mJ/m² or less, more preferably 26 mJ/m² or less, and even more preferably 25 mJ/m² or less.

The difference between the surface free energy of the copolymer B and the surface free energy of the copolymer A (i.e., the value of: (surface free energy of the copolymer A)−(surface free energy of the copolymer B)) is required to be 4 mJ/m² or more, is preferably 5.5 mJ/m² or more, more preferably 6 mJ/m² or more, and even more preferably 6.5 mJ/m² or more, and is preferably 12 mJ/m² or less, more preferably 11 mJ/m² or less, and even more preferably 10 mJ/m² or less.

From a viewpoint of further increasing the contrast of a resist pattern, it is preferable that the copolymer B includes the monomer unit (V) represented by formula (V) that was described in the “Copolymer A” section. Note that since the monomer unit (V) that can be included in the copolymer B can be the same as the monomer unit (V) described in the “Copolymer A” section, description thereof is omitted here.

The proportion constituted by the monomer unit (V) among all monomer units of the copolymer B can be set as 30 mol % or more, preferably 40 mol % or more, and more preferably 45 mol % or more, and can be set as 70 mol % or less, preferably 60 mol % or less, and more preferably 55 mol % or less, for example, without any specific limitations.

From a viewpoint of even further increasing the contrast of a resist pattern, the copolymer B that is contained in the presently disclosed positive resist composition more preferably includes: a monomer unit (III) represented by formula (III), shown below,

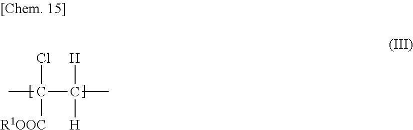

(in formula (III), R¹ is an organic group including not fewer than 5 and not more than 7 fluorine atoms); and a monomer unit (IV) represented by formula (IV), shown below,

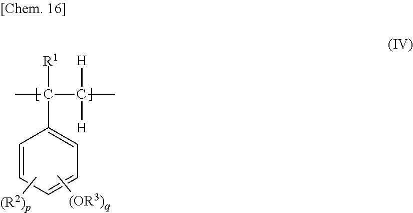

(in formula (IV), R¹ is an alkyl group, R² is a hydrogen atom, a fluorine atom, an unsubstituted alkyl group, or a fluorine atom-substituted alkyl group, R³ is a hydrogen atom, an unsubstituted alkyl group, or a fluorine atom-substituted alkyl group, p and q are integers of not less than 0 and not more than 5, and p+q=5).

Note that although the copolymer B may also include any monomer units other than the monomer unit (III) and the monomer unit (IV), the proportion constituted by the monomer unit (III) and the monomer unit (IV) among all monomer units of the copolymer B is, in total, preferably 90 mol % or more, and more preferably 100 mol % (i.e., the copolymer B more preferably only includes the monomer unit (III) and the monomer unit (IV)).

The copolymer B undergoes efficient main chain scission to lower molecular weight upon irradiation with an electron beam or the like as a result of including the monomer unit (III) and the monomer unit (IV). Moreover, as a result of the monomer unit (III) preferably including a fluorine atom in the copolymer B, it is possible to easily adjust the surface free energy of the copolymer B, to provide resistance to forward scattering and backscattering by an electron beam and leaked light such as EUV, and to further increase pattern contrast when using the presently disclosed positive resist composition.

### <Monomer Unit (III)>

The monomer unit (III) is a structural unit that is derived from a monomer (c) represented by the following formula (c).

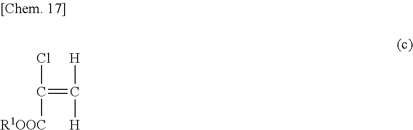

(In formula (c), R¹ is the same as in formula (III).)

The carbon number of R¹ in formula (III) and formula (c) is preferably not less than 2 and not more than 10, and more preferably 5 or less. When the carbon number is not less than the lower limit set forth above, solubility in a developer can be sufficiently improved. Moreover, when the carbon number is not more than any of the upper limits set forth above, clarity of a resist pattern can be sufficiently ensured.

Specifically, R¹ in formula (III) and formula (c) is preferably a fluoroalkyl group, a fluoroalkoxyalkyl group, or a fluoroalkoxyalkenyl group, and is more preferably a fluoroalkyl group. When R¹ is any of the groups set forth above, main chain scission properties of the copolymer B upon irradiation with an electron beam or the like can be sufficiently improved. The fluoroalkyl group may be a 2,2,3,3,3-pentafluoropropyl group

(number of fluorine atoms: 5; carbon number: 3), a 3,3,4,4,4-pentafluorobutyl group (number of fluorine atoms: 5; carbon number: 4), a 1H-1-(trifluoromethyl)trifluoroethyl group (number of fluorine atoms: 6; carbon number: 3), a 1H, 1H,3H-hexafluorobutyl group (number of fluorine atoms: 6; carbon number: 4), a 2,2,3,3,4,4,4-heptafluorobutyl group (number of fluorine atoms: 7; carbon number: 4), a 1,2,2,2-tetrafluoro-1-(trifluoromethyl)ethyl group (number of fluorine atoms: 7; carbon number: 3), or the like, for example. Of these fluoroalkyl groups, a 2,2,3,3,3-pentafluoropropyl group (number of fluorine atoms: 5; carbon number: 3) or a 2,2,3,3,4,4,4-heptafluorobutyl group (number of fluorine atoms: 7; carbon number: 4) is preferable, and a 2,2,3,3,3 -pentafluoropropyl group (number of fluorine atoms: 5; carbon number: 3) is more preferable.

Moreover, the fluoroalkoxyalkyl group may be a fluoroethoxymethyl group, a fluoroethoxyethyl group, or the like, for example.

Furthermore, the fluoroalkoxyalkenyl group may be a fluoroethoxyvinyl group or the like, for example.

The monomer (c) represented by the above-described formula (c) that can form the monomer unit (III) represented by the above-described formula (III) may be an α-chloroacrylic acid fluoroalkyl ester such as 2,2,3,3,3-pentafluoropropyl α-chloroacrylate, 3,3,4,4,4-pentafluorobutyl α-chloroacrylate, 1H-1-(trifluoromethyl)trifluoroethyl α-chloroacrylate, 1H, 1H,3H-hexafluorobutyl α-chloroacrylate, 1,2,2,2-tetrafluoro-1 -(trifluoromethyl)ethyl α-chloroacrylate, or 2,2,3,3,4,4,4-heptafluorobutyl α-chloroacrylate; an α-chloroacrylic acid fluoroalkoxyalkyl ester such as pentafluoroethoxymethyl α-chloroacrylate or pentafluoroethoxyethyl α-chloroacrylate; an α-chloroacrylic acid fluoroalkoxyalkenyl ester such as pentafluoroethoxyvinyl α-chloroacrylate; or the like, for example, without any specific limitations.

Note that from a viewpoint of further improving main chain scission properties of the copolymer B upon irradiation with an electron beam or the like, the monomer unit (III) is preferably a structural unit derived from an α-chloroacrylic acid fluoroalkyl ester.

The proportion constituted by the monomer unit (III) among all monomer units of the copolymer B can be set as 30 mol % or more, preferably 40 mol % or more, and more preferably 45 mol % or more, and can be set as 70 mol % or less, preferably 60 mol % or less, and more preferably 55 mol % or less, for example, without any specific limitations.

The monomer unit (IV) is a structural unit that is derived from a monomer (d) represented by the following general formula (d).

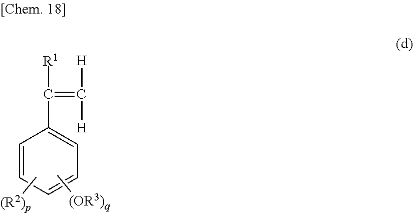

(In formula (d), R¹ to R³, p, and q are the same as in formula (IV).)

The alkyl group that can constitute R¹ in formula (IV) and formula (d) may be an alkyl group having a carbon number of not less than 1 and not more than 5 without any specific limitations. In particular, the alkyl group that can constitute R¹ is preferably a methyl group or an ethyl group.

The unsubstituted alkyl group that can constitute R² and R³ in formulae (IV) and (d) may be an unsubstituted alkyl group having a carbon number of not less than 1 and not more than 5 without any specific limitations. In particular, the unsubstituted alkyl group that can constitute R² and R³ is preferably a methyl group or an ethyl group.

The fluorine atom-substituted alkyl group that can constitute R² and R³ in formulae (IV) and (d) may be a group having a structure in which some or all of the hydrogen atoms in an alkyl group have been replaced with fluorine atoms without any specific limitations.

From a viewpoint of improving ease of production of the copolymer B, the plurality of R² and/or R³ groups that are present in formula (IV) and formula (d) are each preferably a hydrogen atom or an unsubstituted alkyl group, preferably a hydrogen atom or an unsubstituted alkyl group having a carbon number of not less than 1 and not more than 5, and preferably a hydrogen atom.

The monomer (d) represented by the above-described formula (d) that can form the monomer unit (IV) represented by the above-described formula (IV) may be α-methylstyrene (AMS) or a derivative thereof (for example, 4-fluoro-α-methylstyrene: 4FAMS), such as the following monomers (d-1) to (d-11), for example, without any specific limitations.

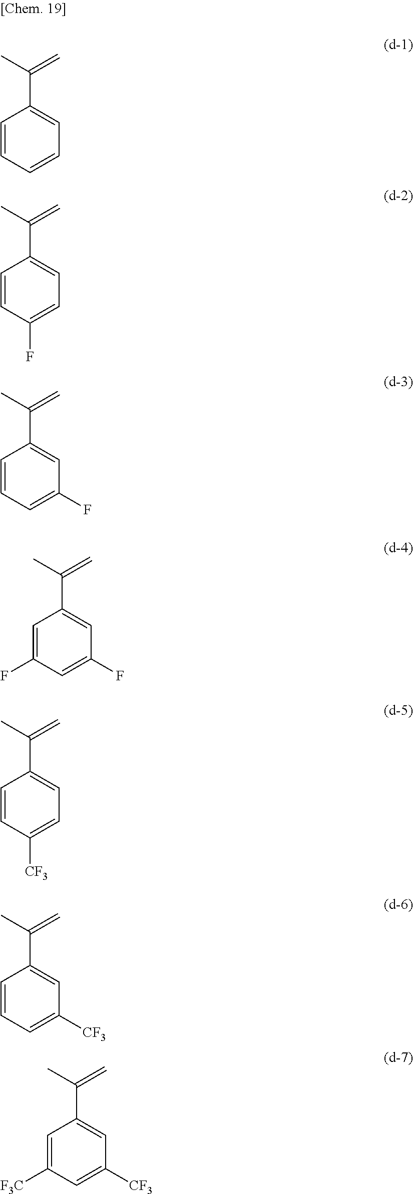

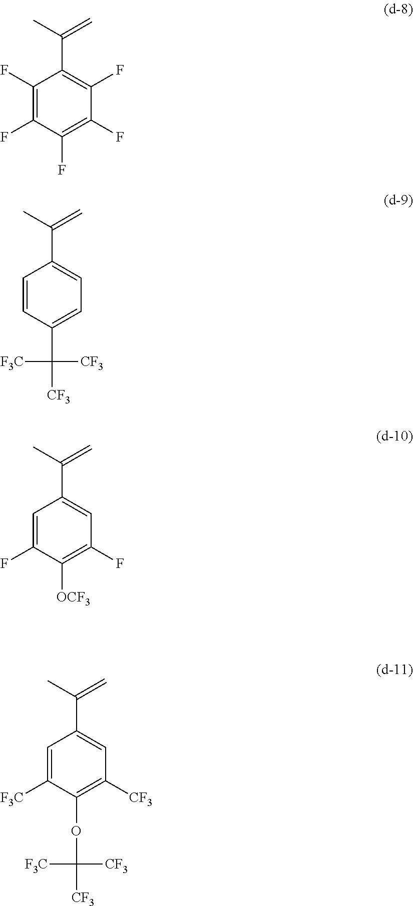

Note that from a viewpoint of improving ease of production of the copolymer B and main chain scission properties of the copolymer B upon irradiation with an electron beam or the like, α-methylstyrene or 4-fluoro-α-methylstyrene is preferable as the monomer (d) represented by the above-described formula (d) that can form the monomer unit (IV). In other words, the copolymer B preferably includes an α-methylstyrene unit or a 4-fluoro-α-methylstyrene unit.

The proportion constituted by the monomer unit (IV) among all monomer units of the copolymer B can be set as 30 mol % or more, preferably 40 mol % or more, and more preferably 45 mol % or more, and can be set as 70 mol % or less, preferably 60 mol % or less, and more preferably 55 mol % or less, for example, without any specific limitations.

### <Properties of Copolymer B>

### [Weight-Average Molecular Weight (Mw)]

The weight-average molecular weight (Mw) of the copolymer B is preferably 10,000 or more, more preferably 17,000 or more, and even more preferably 25,000 or more, and is preferably 250,000 or less, more preferably 180,000 or less, and even more preferably 50,000 or less. When the weight-average molecular weight (Mw) of the copolymer B is not less than any of the lower limits set forth above, solubility of a resist film in a developer can be restricted from increasing excessively at a low irradiation dose. Moreover, when the weight-average molecular weight (Mw) of the copolymer B is not more than any of the upper limits set forth above, the positive resist composition can easily be adjusted.

### [Number-Average Molecular Weight (Mn)]

The number-average molecular weight (Mn) of the copolymer B is preferably 7,000 or more, and more preferably 10,000 or more, and is preferably 150,000 or less. When the number-average molecular weight of the copolymer B is not less than any of the lower limits set forth above, solubility of a resist film in a developer can be further restricted from increasing excessively at a low irradiation dose, and a resist pattern having further improved contrast can be formed. Moreover, when the number-average molecular weight of the copolymer B is not more than the upper limit set forth above, the positive resist composition is even easier to produce.

### [Molecular Weight Distribution (Mw/Mn)]

The molecular weight distribution (Mw/Mn) of the copolymer B is preferably 1.10 or more, and more preferably 1.20 or more, and is preferably 1.70 or less, and more preferably 1.65 or less. When the molecular weight distribution (Mw/Mn) of the copolymer B is not less than any of the lower limits set forth above, ease of production of the copolymer B can be increased. Moreover, when the molecular weight distribution (Mw/Mn) of the copolymer B is not more than any of the upper limits set forth above, the contrast of an obtained resist pattern can be further increased.

### [Production Method of Copolymer B]

No specific limitations are placed on the method by which the copolymer B is produced. For example, a copolymer B that includes the previously described monomer unit (V) can be produced by carrying out polymerization of a monomer composition that contains the monomer (e) and any monomer that is copolymerizable with the monomer (e), and then collecting and optionally purifying the resultant copolymer. The polymerization method and purification method are not specifically limited and can be the same as the polymerization method and the purification method for the copolymer A described above. Moreover, it is preferable to use a polymerization initiator in production of the copolymer B. For example, a polymerization initiator such as azobisisobutyronitrile can suitably be used.

### <Solvent>

The solvent is not specifically limited so long as it is a solvent in which the copolymer A and the copolymer B described above can dissolve. For example, known solvents such as those described in JP5938536B1 can be used. Of such solvents, anisole, propylene glycol monomethyl ether acetate (PGMEA), cyclopentanone, cyclohexanone, or isoamyl acetate is preferable as the solvent from a viewpoint of obtaining a positive resist composition of suitable viscosity and improving coatability of the positive resist composition.

### <Production of Positive Resist Composition>

The positive resist composition can be produced by mixing the above-described copolymer A, copolymer B, solvent, and known additives that can optionally be used. From a viewpoint of further reducing resist pattern top loss and further increasing the contrast of a resist pattern, it is preferable that the copolymer A and the copolymer B are both main chain scission-type copolymers that include a halogen atom, and more preferable that the copolymer A and the copolymer B both include a fluorine substituent, that at least one of the aforementioned halogen atom is a fluorine atom, and that the fluorine atom is included in the fluorine substituent. It is even more preferable that either the copolymer A or the copolymer B preferably includes a monomer unit represented by the above-described formula (V), and that the copolymer A and the copolymer B more preferably both include a monomer unit represented by the above-described formula (V). Moreover, it is particularly preferable that the copolymer A includes the monomer unit (I) represented by formula (I) and the monomer unit (II) represented by formula (II) that were previously described and that the copolymer B includes the monomer unit represented by formula (III) and the monomer unit (IV) represented by formula (IV) that were previously described. The method of mixing of the above-described components in production of the positive resist composition is not specifically limited, and may be mixing by a commonly known method. Moreover, production may be performed by filtering the mixture after mixing of components.

### [Filtration]

No specific limitations are placed on the method by which the mixture is filtered. For example, the mixture can be filtered using a filter. The filter is not specifically limited and may, for example, be a filtration membrane based on a fluorocarbon, cellulose, nylon, polyester, hydrocarbon, or the like. In particular, from a viewpoint of effectively preventing impurities such as metals from becoming mixed into the positive resist composition from metal piping or the like that may be used in production of the copolymer A and the copolymer B, the constituent material of the filter is preferably polyethylene, polypropylene, a polyfluorocarbon such as polytetrafluoroethylene or Teflon® (Teflon is a registered trademark in Japan, other countries, or both), tetrafluoroethylene-perfluoroalkyl vinyl ether copolymer (PFA), nylon, a composite membrane of polyethylene and nylon, or the like. For example, a filter disclosed in U.S. Pat. No. 6,103,122A may be used as the filter. Moreover, the filter may be a commercially available product such as Zeta Plus® 40Q (Zeta Plus is a registered trademark in Japan, other countries, or both) produced by CUNO Incorporated. Furthermore, the filter may be a filter that contains a strongly cationic or weakly cationic ion exchange resin. The average particle diameter of the ion exchange resin is not specifically limited but is preferably not less than 2 μm and not more than 10 μm. Examples of cation exchange resins that may be used include a sulfonated phenol-formaldehyde condensate, a sulfonated phenol-benzaldehyde condensate, a sulfonated styrene-divinylbenzene copolymer, a sulfonated methacrylic acid-divinylbenzene copolymer, and other types of sulfo or carboxyl group-containing polymers. In the cation exchange resin, H⁺ counter ions, NH₄⁺ counter ions, or alkali metal counter ions such as K⁺ or Na⁺ counter ions are provided. The cation exchange resin preferably includes hydrogen counter ions. One example of such a cation exchange resin is Microlite® PrCH (Microlite is a registered trademark in Japan, other countries, or both) produced by Purolite, which is a sulfonated styrene-divinylbenzene copolymer including H⁺ counter ions. Another example of such a cation exchange resin is commercially available as AMBERLYST® (AMBERLYST is a registered trademark in Japan, other countries, or both) produced by Rohm and Haas Company.

The pore diameter of the filter is preferably not less than 0.001 μm and not more than 1 μm. When the pore diameter of the filter is within the range set forth above, it is possible to sufficiently prevent impurities such as metals from being mixed into the positive resist composition.

### <Proportions of Copolymer A and Copolymer B>

Although no specific limitations are placed on the proportions constituted by the copolymer A and the copolymer B in the presently disclosed positive resist composition, the proportion constituted by the copolymer B is preferably 1 mass % or more, more preferably 5 mass % or more, and even more preferably 10 mass % or more per 100 mass %, in total, of the copolymer A and the copolymer B, and is preferably 30 mass % or less, more preferably 25 mass % or less, and even more preferably 20 mass % or less per 100 mass %, in total, of the copolymer A and the copolymer B. When the proportion constituted by the copolymer B is not less than any of the lower limits set forth above, solubility of a resist film in a developer can be restricted from increasing excessively at a low irradiation dose, and a resist pattern having further improved contrast can be formed. Moreover, when the proportion constituted by the copolymer B is not more than any of the upper limits set forth above, deterioration of sensitivity of a positive resist can be suppressed.

### (Method of Forming Resist Pattern)

The presently disclosed method of forming a resist pattern includes at least forming a resist film using the presently disclosed positive resist composition set forth above (resist film formation step), exposing the resist film (exposure step), and developing the resist film that has been exposed (development step).

Note that the presently disclosed method of forming a resist pattern may further include steps other than the resist film formation step, exposure step, and development step described above. More specifically, the presently disclosed method of forming a resist pattern may include forming a lower layer film on a substrate on which a resist film is to be formed (lower layer film formation step) in advance of the resist film formation step. Moreover, the presently disclosed method of forming a resist pattern may include heating the resist film that has been exposed (post exposure bake step) between the exposure step and the development step. Furthermore, the presently disclosed method of forming a resist pattern may further include removing the developer (rinsing step) after the development step. After a resist pattern has been formed by the presently disclosed method of forming a resist pattern, etching the lower layer film and/or the substrate (etching step) may be further included.

As a result of a positive resist composition that contains the specific copolymer A and copolymer B being used as a positive resist composition in the presently disclosed method of forming a resist pattern, it is possible to reduce resist pattern top loss and form a resist pattern having high contrast.

### (Resist Film Formation Step)

In the resist film formation step, the presently disclosed positive resist composition is applied onto a workpiece, such as a substrate, that is to be processed using a resist pattern, and the applied positive resist composition is dried to form a resist film.

### Substrate

The substrate on which a resist film can be formed in the method of forming a resist pattern is not specifically limited and may, for example, be a mask blank including a light shielding layer formed on a substrate or a substrate including an electrically insulating layer and copper foil on the electrically insulating layer that is used in production of a printed board or the like.

The material of the substrate may, for example, be an inorganic material such as a metal (silicon, copper, chromium, iron, aluminum, etc.), glass, titanium oxide, silicon dioxide (SiO₂), silica, or mica; a nitride such as SiN; an oxynitride such as SiON; or an organic material such as acrylic, polystyrene, cellulose, cellulose acetate, or phenolic resin. Of these materials, a metal is preferable as the material of the substrate. By using a silicon substrate, a silicon dioxide substrate, or a copper substrate, and preferably a silicon substrate or a silicon dioxide substrate as the substrate, it is possible to form a structure having a cylinder structure.

No specific limitations are placed on the size and shape of the substrate. Note that the surface of the substrate may be smooth or may have a curved or irregular shape, and that a substrate having a flake shape or the like may be used.

Moreover, the surface of the substrate may be subjected to surface treatment as necessary. For example, in the case of a substrate having hydroxyl groups in a surface layer thereof, the substrate can be surface treated using a silane coupling agent that can react with hydroxyl groups. This makes it possible to convert the surface layer of the substrate from hydrophilic to hydrophobic and to increase close adherence between the substrate and a lower layer film or between the substrate and a resist film. The silane coupling agent is not specifically limited but is preferably hexamethyldisilazane.

### (Lower Layer Film Formation Step)

In the lower layer film formation step that can optionally be performed, a lower layer film is formed on the substrate. Through provision of the lower layer film on the substrate, the surface of the substrate is hydrophobized. This can increase affinity of the substrate and a resist film and can increase close adherence between the substrate and the resist film. The lower layer film may be an inorganic lower layer film or an organic lower layer film.

An inorganic lower layer film can be formed by applying an inorganic material onto the substrate and then performing firing or the like of the inorganic material. The inorganic material may be a silicon-based material or the like, for example.

An organic lower layer film can be formed by applying an organic material onto the substrate to form a coating film and then drying the coating film. The organic material is not limited to being a material that is sensitive to light or an electron beam and may be a resist material or resin material that is typically used in the field of semiconductors or the field of liquid crystals, for example. In particular, the organic material is preferably a material that can form an organic lower layer film that can be etched, and particularly dry etched. By using such an organic material, it is possible to etch the organic lower layer film using a pattern formed through processing of a resist film, and to thereby transfer the pattern to the lower layer film and form a lower layer film pattern. In particular, the organic material is preferably a material that can form an organic lower layer film that can be etched by oxygen plasma etching or the like. For example, AL412 produced by Brewer Science, Inc. or the like may be used as an organic material that is used to form an organic lower layer film.

Application of the organic material described above can be performed by spin coating or a conventional and commonly known method using a spinner or the like. The method by which the coating film is dried may be any method that can cause volatilization of solvent contained in the organic material. For example, a method in which baking is performed or the like may be adopted. Although no specific limitations are placed on the baking conditions, the baking temperature is preferably not lower than 80° C. and not higher than 300° C., and more preferably not lower than 200° C. and not higher than 300° C. Moreover, the baking time is preferably 30 seconds or more, and more preferably 60 seconds or more, and is preferably 500 seconds or less, more preferably 400 seconds or less, even more preferably 300 seconds or less, and particularly preferably 180 seconds or less. Furthermore, the thickness of the lower layer film after drying of the coating film is not specifically limited but is preferably not less than 10 nm and not more than 100 nm.

### (Resist Film Formation Step)

In the resist film formation step, the positive resist composition is applied onto a workpiece, such as a substrate, that is to be processed using a resist pattern (onto a lower layer film in a case in which a lower layer film has been formed), and the applied positive resist composition is dried to form a resist film.

The application method and the drying method of the positive resist composition can be methods that are typically used in the formation of a resist film without any specific limitations. In particular, the method of drying is preferably heating (prebaking). The prebaking temperature is preferably 100° C. or higher, more preferably 120° C. or higher, and even more preferably 140° C. or higher from a viewpoint of improving film density of the resist film. Moreover, the prebaking temperature is preferably 250° C. or lower, more preferably 220° C. or lower, and even more preferably 200° C. or lower from a viewpoint of reducing change of the molecular weight and molecular weight distribution of the copolymer A and the copolymer B in the resist film between before and after prebaking. Furthermore, the prebaking time is preferably 10 seconds or more, more preferably 20 seconds or more, and even more preferably 30 seconds or more from a viewpoint of improving film density of the resist film formed through prebaking. Also, the prebaking time is preferably 10 minutes or less, more preferably 5 minutes or less, and even more preferably 3 minutes or less from a viewpoint of further reducing change of the molecular weight and molecular weight distribution of the copolymer A and the copolymer B in the resist film between before and after prebaking.

### (Exposure Step)

In the exposure step, the resist film formed in the resist film formation step is irradiated with ionizing radiation or the like (electron beam, EUV, etc.) to write a desired pattern. Note that irradiation with an electron beam can be performed using a known writing tool such as an electron beam lithography tool or an EUV exposure tool.

### (Post Exposure Bake Step)

In the post exposure bake step that can optionally be performed, the resist film that has been exposed in the exposure step is heated. By performing the post exposure bake step, it is possible to reduce the surface roughness of a resist pattern.

The heating temperature is preferably 70° C. or higher, more preferably 80° C. or higher, and even more preferably 90° C. or higher, and is preferably 200° C. or lower, more preferably 170° C. or lower, and even more preferably 150° C. or lower. When the heating temperature is within any of the ranges set forth above, clarity of a resist pattern can be increased while also favorably reducing surface roughness of the resist pattern.

The time for which the resist film is heated (heating time) in the post exposure bake step is preferably 10 seconds or more, more preferably 20 seconds or more, and even more preferably 30 seconds or more. When the heating time is 10 seconds or more, clarity of a resist pattern can be further increased while also sufficiently reducing surface roughness of the resist pattern. On the other hand, the heating time is preferably 10 minutes or less, more preferably 5 minutes or less, and even more preferably 3 minutes or less, for example, from a viewpoint of production efficiency.

The method by which the resist film is heated in the post exposure bake step is not specifically limited and may, for example, be a method in which the resist film is heated by a hot plate, a method in which the resist film is heated in an oven, or a method in which hot air is blown against the resist film.

### (Development Step)

In the development step, the resist film that has been exposed (resist film that has been exposed and heated in a case in which the post exposure bake step is performed) is developed to form a developed film on the workpiece.

Development of the resist film can be performed by bringing the resist film into contact with a developer, for example. The method by which the resist film and the developer are brought into contact may be, but is not specifically limited to, a method using a known technique such as immersion of the resist film in the developer or application of the developer onto the resist film.

<Developer>

The developer can be selected as appropriate depending on properties of the previously described copolymer A and copolymer B, for example. Specifically, in selection of the developer, it is preferable to select a developer that does not dissolve a resist film prior to the exposure step being performed but that can dissolve an exposed part of a resist film that has undergone the exposure step. One developer may be used individually, or two or more developers may be used as a mixture in a freely selected ratio.

Examples of developers that can be used include fluorinated solvents such as hydrofluorocarbons (1,1,1,2,3,4,4,5,5,5-decafluoropentane (CF₃CFHCFHCF₂CF₃), 1,1,1,2,2,3,3,4,4,5,5,6,6-tridecafluorohexane, 1,1,1,2,2,3,4,5,5,5-decafluoropentane, 1,1,1,3,3-pentafluorobutane, 1,1,1,2,2,3,3,4,4-nonafluorohexane, etc.), hydrochlorofluorocarbons (2,2-dichloro-1, 1,1-trifluoroethane, 1,1-dichloro-1-fluoroethane, 1,1-dichloro-2,2,3,3,3-pentafluoropropane (CF₃CF₂CHCl₂), 1,3-dichloro-1,1,2,2,3-pentafluoropropane (CClF₂CF₂CHClF), etc.), hydrofluoroethers (methyl nonafluorobutyl ether (CF₃CF₂CF₂CF₂OCH₃), methyl nonafluoroisobutyl ether, ethyl nonafluorobutyl ether (CF₃CF₂CF₂CF₂OC₂H₅), ethyl nonafluoroisobutyl ether, perfluorohexyl methyl ether (CF₃CF₂CF(OCH₃)C₃F₇), etc.), and perfluorocarbons (CF₄, C₂F₆, C₃F₈, C₄F₈, C+F₁₀, C₅F₁₂, C₆F₁₂, C₆F₁₄, C₇F₁₄, C₇F₁₆, C₈F₁₈, C₉F₂₀, etc.); alcohols such as methanol, ethanol, 1-propanol, 2-propanol (isopropyl alcohol), 1-butanol, 2-butanol, 1-pentanol, 2-pentanol, and 3-pentanol; acetic acid esters including an alkyl group such as amyl acetate and hexyl acetate; mixtures of a fluorinated solvent and an alcohol; mixtures of a fluorinated solvent and an acetic acid ester including an alkyl group;

mixtures of an alcohol and an acetic acid ester including an alkyl group; and mixtures of a fluorinated solvent, an alcohol, and an acetic acid ester including an alkyl group. Of these developers, an alcohol such as 2-butanol or isopropyl alcohol is preferably used to perform development from a viewpoint of even further increasing the contrast of a resist pattern.

The temperature of the developer during development is not specifically limited and can be set as not lower than 5° C. and not higher than 40° C., for example. Moreover, the development time can be set as not less than 10 seconds and not more than 4 minutes, for example.

### (Rinsing Step)

In the presently disclosed method of forming a resist pattern, removing the developer can be performed after the development step. The removing of the developer can be performed using a rinsing liquid, for example.

Specific examples of rinsing liquids that may be used include the same liquids as the developers given as examples in the “Development step” section, and also hydrocarbon solvents such as octane and heptane, and water, for example. The rinsing liquid may contain a surfactant. In selection of the rinsing liquid, it is preferable to select a rinsing liquid that, compared to the developer used in the development step, has a lower tendency to dissolve the resist film prior to the exposure step being performed and that readily mixes with the developer.

The temperature of the rinsing liquid during rinsing is not specifically limited and can be set as not lower than 5° C. and not higher than 40° C., for example. Moreover, the rinsing time can be set as not less than 5 seconds and not more than 3 minutes, for example.

The developer and rinsing liquid described above may each be filtered prior to use. The filtration method may be a filtration method using a filter such as previously described in the “Production of positive resist composition” section, for example.

### (Etching Step)

In the etching step that can optionally be performed, etching of the lower layer film and/or the substrate is performed using the above-described resist pattern as a mask so as to form a pattern in the lower layer film and/or substrate.

The number of times that etching is performed is not specifically limited and may be once or a plurality of times. Moreover, the etching may be dry etching or wet etching, but is preferably dry etching. The dry etching can be performed using a commonly known dry etching apparatus. An etching gas that is used in the dry etching can be selected as appropriate depending on the element composition of the lower layer film or substrate that is to be etched, for example. Examples of etching gases that may be used include fluorine-based gases such as CHF₃, CF₄, C₂F₆, C₃F₈, and SF₆; chlorine-based gases such as Cl₂ and BCl₃; oxygen-based gases such as O₂, O₃, and H₂O; reducing gases such as H₂, NH₃, CO, CO₂, CH₄, C₂H₂, C₂H₄, C₂H₆, C₃H₄, C₃H₆, C₃H₈, HF, HI, HBr, HCI, NO, NH₃, and BCl₃; and inert gases such as He, N₂, and Ar. One of these gases may be used individually, or two or more of these gases may be used as a mixture. Note that dry etching of an inorganic lower layer film is usually performed using an oxygen-based gas. Moreover, dry etching of a substrate is normally performed using a fluorine-based gas and may suitably be performed using a mixture of a fluorine-based gas and an inert gas.

Lower layer film remaining on the substrate may be removed before etching of the substrate or after etching of the substrate as necessary. In a case in which the lower layer film is removed before etching of the substrate is performed, this lower layer film may be a lower layer film in which a pattern is formed or may be a lower layer film in which a pattern is not formed.

The method by which the lower layer film is removed may, for example, be dry etching such as described above. In the case of an inorganic lower layer film, the lower layer film may be removed by bringing a liquid such as a basic liquid or an acidic liquid, and preferably a basic liquid into contact with the lower layer film. The basic liquid is not specifically limited and may be alkaline hydrogen peroxide aqueous solution or the like, for example. The method by which the lower layer film is removed through wet stripping using alkaline hydrogen peroxide aqueous solution is not specifically limited so long as it is a method in which the lower layer film and alkaline hydrogen peroxide aqueous solution can be brought into contact under heated conditions for a specific time and may, for example, be a method in which the lower layer film is immersed in heated alkaline hydrogen peroxide aqueous solution, a method in which alkaline hydrogen peroxide aqueous solution is sprayed against the lower layer film in a heated environment, or a method in which heated alkaline hydrogen peroxide aqueous solution is applied onto the lower layer film. After any of these methods is performed, the substrate may be washed with water and then dried to thereby obtain a substrate from which the lower layer film has been removed.

The following describes one example of the presently disclosed method of forming a resist pattern using a positive resist and a method of etching a lower layer film and a substrate using a resist pattern that is formed. However, since the substrate, conditions of each step, and so forth in the following example can be the same as the substrate, conditions of each step, and so forth described above, description thereof is omitted below. Note that the presently disclosed method of forming a resist pattern is not limited to the method presented in the following example.

One example of the method of forming a resist pattern is a method of forming a resist pattern using an electron beam or EUV that includes the previously described lower layer film formation step, resist film formation step, exposure step, development step, and rinsing step. Moreover, one example of the etching method is a method in which a resist pattern formed by the method of forming a resist pattern is used as a mask and that includes an etching step.

Specifically, in the lower layer film formation step, an inorganic material is applied onto a substrate and is fired to form an inorganic lower layer film.

Next, in the resist film formation step, the presently disclosed positive resist composition is applied onto the inorganic lower layer film that has been formed in the lower layer film formation step and is dried to form a resist film.

The resist film that is formed in the resist film formation step is then irradiated with EUV in the exposure step so as to write a desired pattern.

Moreover, in the development step, the resist film that has been exposed in the exposure step and a developer are brought into contact to develop the resist film and form a resist pattern on the lower layer film.

In the rinsing step, the resist film that has been developed in the development step and a rinsing liquid are brought into contact to rinse the developed resist film.

In the etching step, the resist pattern is used as a mask to etch the lower layer film and thereby form a pattern in the lower layer film.

The lower layer film in which the pattern has been formed is then used as a mask to etch the substrate and thereby form a pattern in the substrate.

### (Etching Resistance of Resist Film)

A resist film obtained by the presently disclosed method of forming a resist pattern has excellent etching resistance, and, in particular, has excellent dry etching resistance. Note that the dry etching resistance of the resist film tends to be better when the carbon content per unit volume of the copolymer A and the copolymer B contained in the positive resist composition is higher.

Through the presently disclosed method of forming a resist pattern, it is possible to obtain a laminate including a resist film having a two-layer structure such as described below, for example.

### (Laminate)

A laminate obtained by the presently disclosed method of producing a resist pattern includes a substrate and a resist film formed on the substrate. The resist film includes a lower layer that is disposed on the substrate and an upper layer that is disposed on the lower layer. The lower layer is formed from the previously described copolymer A, and the upper layer is formed from the previously described copolymer B. The resist film that is included in the presently disclosed laminate can be formed by the presently disclosed method of forming a resist pattern.

### EXAMPLES

The following provides a more specific description of the present disclosure based on examples. However, the present disclosure is not limited to the following examples.

In the examples and comparative examples, the following method was used to measure the number-average molecular weight, weight-average molecular weight, and molecular weight distribution of a copolymer.

### NUMBER-AVERAGE MOLECULAR WEIGHT, WEIGHT-AVERAGE MOLECULAR WEIGHT, AND MOLECULAR WEIGHT DISTRIBUTION

For each obtained copolymer A or copolymer B, the number-average molecular weight (Mn) and weight-average molecular weight (Mw) of the copolymer were measured by gel permeation chromatography, and then the molecular weight distribution (Mw/Mn) of the copolymer was calculated.

Specifically, the number-average molecular weight (Mn) and weight-average molecular weight (Mw) of the copolymer were determined as standard polystyrene-equivalent values with tetrahydrofuran as an eluent solvent using a gel permeation chromatograph (HLC-8220 produced by Tosoh Corporation). The molecular weight distribution (Mw/Mn) was then calculated. Note that each obtained copolymer A or copolymer B was confirmed to not substantially contain a component having a weight-average molecular weight (Mw) of less than 1,000.

### PRODUCTION OF COPOLYMER A

### Production Example 1: Production of Copolymer A1

### [Synthesis of Polymerized Product]

A glass ampoule in which a stirrer had been placed was charged with a monomer composition containing 3 g of 1-phenyl-1-trifluoromethyl-2,2,2-trifluoroethyl α-chloroacrylate (ACAFPh) as a monomer (a), 2.493 g of α-methylstyrene as a monomer (b), and 2.833 g of cyclopentanone as a solvent. The ampoule was tightly sealed and oxygen was removed from the system through 10 repetitions of pressurization and depressurization with nitrogen gas.

The system was then heated to 30° C. and a reaction was carried out for 80 hours. Next, 10 g of tetrahydrofuran (THF) was added to the system and then the resultant solution was added dropwise to 100 g of methanol (MeOH) as a solvent to cause precipitation of a polymerized product. Thereafter, the polymerized product that had precipitated was collected by filtration. Note that the obtained polymerized product was a copolymer comprising 50 mol % of 1-phenyl-1-trifluoromethyl-2,2,2-trifluoroethyl α-chloroacrylate units and 50 mol % of α-methylstyrene units. Thereafter, the number-average molecular weight, weight-average molecular weight, and molecular weight distribution of the obtained copolymer (pre-purification copolymer A1) were measured. The results are shown in Table 1.

### [Purification of Polymerized Product]

The polymerized product that had been collected by filtration was subsequently dissolved in 10 g of THF and then the resultant solution was added dropwise to 100 g of a mixed solvent of THF and MeOH (THF: MeOH (mass ratio)=29:71) to cause precipitation of a white coagulated material (copolymer comprising 1-phenyl-1-trifluoromethyl-2,2,2-trifluoroethyl α-chloroacrylate units and α-methylstyrene units). The solution containing the precipitated copolymer was subsequently filtered using a Kiriyama funnel to obtain a white copolymer (copolymer comprising 50 mol % of 1-phenyl-1-trifluoromethyl-2,2,2-trifluoroethyl α-chloroacrylate units and 50 mol % of α-methylstyrene units).

Thereafter, the number-average molecular weight, weight-average molecular weight, and molecular weight distribution of the obtained copolymer (post-purification copolymer A1) were measured. The results are shown in Table 1.

### Production Example 2: Production of Copolymer A2

[Production of 18% solid content aqueous solution of partially hydrogenated tallow fatty acid potassium soap]

After preparing 100 g of deionized water and then heating this deionized water to 70° C. under stirring, 8.40 g of potassium hydroxide (49% aqueous solution) was added thereto. Next, 19.6 g of HARDENED TALLOW FATTY ACID 45° HFA (produced by NOF Corporation) was added at an addition rate of 1.28 g/min, and then 0.126 g of potassium silicate was added. At least 2 hours of stirring was performed at 80° C. to yield an 18% solid content aqueous solution of partially hydrogenated tallow fatty acid potassium soap.

### [Synthesis of Polymerized Product]

A glass ampoule in which a stirrer had been placed was charged with 3 of 1-phenyl-1-trifluoromethyl-2,2,2-trifluoroethyl α-chloroacrylate g (ACAFPh) as a monomer (a) and 2.712 g of α-methylstyrene as a monomer (b). In addition, 6.771 g of deionized water relative to 0.5463 g of the 18% solid content aqueous solution of partially hydrogenated tallow fatty acid potassium soap produced as described above was added into the same ampoule to obtain a monomer composition, and then the ampoule was tightly sealed and oxygen was removed from the system through 10 repetitions of pressurization and depressurization with nitrogen gas.

The system was then heated to 40° C. and a polymerization reaction was carried out for 11 hours. Next, 10 g of tetrahydrofuran was added to the system and then the resultant solution was added dropwise to 100 g of MeOH as a solvent to cause precipitation of a polymerized product. Thereafter, the polymerized product that had precipitated was collected by filtration. Note that the obtained polymerized product was a copolymer comprising 50 mol % of 1-phenyl-1-trifluoromethyl-2,2,2-trifluoroethyl α-chloroacrylate units and 50 mol % of α-methylstyrene units.

Thereafter, various measurements were performed with respect to the obtained copolymer (pre-purification copolymer A2) in the same way as in Production Example 1. The results are shown in Table 1.

### [Purification of Polymerized Product]

The polymerized product that had been collected by filtration was subsequently dissolved in 10 g of THF and then the resultant solution was added dropwise to 100 g of a mixed solvent of THF and MeOH (THF: MeOH (mass ratio)=35:65) to cause precipitation of a white coagulated material (copolymer comprising 1-phenyl-1-trifluoromethyl-2,2,2-trifluoroethyl α-chloroacrylate units and α-methylstyrene units). The solution containing the precipitated copolymer was subsequently filtered using a Kiriyama funnel to obtain a white copolymer (copolymer comprising 50 mol % of 1-phenyl-1-trifluoromethyl-2,2,2-trifluoroethyl α-chloroacrylate units and 50 mol % of α-methylstyrene units).

Thereafter, various measurements were performed with respect to the obtained copolymer (post-purification copolymer A2) in the same way as in Production Example 1. The results are shown in Table 1.

### Production Example 3: Production of Copolymer A3

### [Synthesis of Polymerized Product]

A glass ampoule in which a stirrer had been placed was charged with a monomer composition containing 3 g of 1-phenyl-1-trifluoromethyl-2,2,2-trifluoroethyl α-chloroacrylate (ACAFPh) as a monomer (a), 1.066 g of α-methylstyrene as a monomer (b), and 1.743 g of cyclopentanone as a solvent. The ampoule was tightly sealed and oxygen was removed from the system through 10 repetitions of pressurization and depressurization with nitrogen gas.

The system was then heated to 30° C. and a reaction was carried out for 50 hours. Next, 10 g of tetrahydrofuran was added to the system and then the resultant solution was added dropwise to 100 g of MeOH as a solvent to cause precipitation of a polymerized product. Thereafter, the polymerized product that had precipitated was collected by filtration. Note that the obtained polymerized product was a copolymer comprising 54 mol % of 1-phenyl-1-trifluoromethyl-2,2,2-trifluoroethyl α-chloroacrylate units and 46 mol % of α-methylstyrene units.

Thereafter, various measurements were performed with respect to the obtained copolymer (pre-purification copolymer A3) in the same way as in Production Example 1. The results are shown in Table 1.

### [Purification of Polymerized Product]

The polymerized product that had been collected by filtration was subsequently dissolved in 10 g of THF and then the resultant solution was added dropwise to 100 g of a mixed solvent of THF and MeOH (THF:MeOH (mass ratio)=30:70) to cause precipitation of a white coagulated material (copolymer comprising 1-phenyl-1-trifluoromethyl-2,2,2-trifluoroethyl α-chloroacrylate units and α-methylstyrene units). The solution containing the precipitated copolymer was subsequently filtered using a Kiriyama funnel to obtain a white copolymer (copolymer comprising 54 mol % of 1-phenyl-1-trifluoromethyl-2,2,2-trifluoroethyl α-chloroacrylate units and 46 mol % of α-methylstyrene units).

Thereafter, various measurements were performed with respect to the obtained copolymer (post-purification copolymer A3) in the same way as in Production Example 1. The results are shown in Table 1.

### Production Example 4: Production of Copolymer A4

### [Synthesis of Polymerized Product]

A glass ampoule in which a stirrer had been placed was charged with 3 g of 1-phenyl-1-trifluoromethyl-2,2,2-trifluoroethyl α-chloroacrylate (ACAFPh) as a monomer (a) and 1.066 g of α-methylstyrene as a monomer (b). In addition, 6.771 g of deionized water relative to 0.5463 g of the 18% solid content aqueous solution of partially hydrogenated tallow fatty acid potassium soap produced in Production Example 2 was added into the same ampoule to obtain a monomer composition, and then the ampoule was tightly sealed and oxygen was removed from the system through 10 repetitions of pressurization and depressurization with nitrogen gas.

The system was then heated to 75° C. and a polymerization reaction was carried out for 1 hour. Next, 10 g of tetrahydrofuran was added to the system and then the resultant solution was added dropwise to 100 g of a mixed solvent of THF and MeOH (THF: MeOH (mass ratio)=30:70) to cause precipitation of a polymerized product. Thereafter, the polymerized product that had precipitated was collected by filtration. Note that the obtained polymerized product was a copolymer comprising 54 mol % of 1-phenyl-1-trifluoromethyl-2,2,2-trifluoroethyl α-chloroacrylate units and 46 mol % of α-methylstyrene units.

Thereafter, various measurements were performed with respect to the obtained copolymer (pre-purification copolymer A4) in the same way as in Production Example 1. The results are shown in Table 1.

### [Purification of Polymerized Product]

The polymerized product that had been collected by filtration was subsequently dissolved in 10 g of THF and then the resultant solution was added dropwise to 100 g of a mixed solvent of THF and MeOH (THF: MeOH (mass ratio)=34:66) to cause precipitation of a white coagulated material (copolymer comprising 1-phenyl-1-trifluoromethyl-2,2,2-trifluoroethyl α-chloroacrylate units and α-methylstyrene units). The solution containing the precipitated copolymer was subsequently filtered using a Kiriyama funnel to obtain a white copolymer (copolymer comprising 54 mol % of 1-phenyl-1-trifluoromethyl-2,2,2-trifluoroethyl α-chloroacrylate units and 46 mol % of α-methylstyrene units).

Thereafter, various measurements were performed with respect to the obtained copolymer (post-purification copolymer A4) in the same way as in Production Example 1. The results are shown in Table 1.

### Production Example 5: Production of Copolymer A5

### [Synthesis of Polymerized Product]

A copolymer (pre-purification copolymer A5) was obtained by performing the same operations as in Production Example 4 with the exception that in synthesis of the polymerized product, the mass ratio of THF and MeOH in the mixed solvent used for precipitation of the polymerized product was changed to 33:67.

Thereafter, various measurements were performed with respect to the obtained copolymer (pre-purification copolymer A5) in the same way as in Production Example 1. The results are shown in Table 1.

### [Purification of Polymerized Product]

A copolymer was obtained by performing the same operations as in Production Example 4 with the exception that the mass ratio of THF and MeOH in the mixed solvent used for purification of the polymerized product was changed to 33:67 and that purification was performed twice.

Thereafter, various measurements were performed with respect to the obtained copolymer (post-purification copolymer A5) in the same way as in Production Example 1. The results are shown in Table 1.

### Production Example 6: Production of copolymer A6

### [Synthesis of Polymerized Product]

A glass ampoule in which a stirrer had been placed was charged with 3 g of 1-(4-methoxyphenyl)-1-trifluoromethyl-2,2,2-trifluoroethyl chloroacrylate (ACAFPhOMe) as a monomer (a) and 2.487 g of α-methylstyrene as a monomer (b). In addition, 6.771 g of deionized water relative to 0.5463 g of the 18% solid content aqueous solution of partially hydrogenated tallow fatty acid potassium soap produced in Production Example 2 was added into the same ampoule to obtain a monomer composition, and then the ampoule was tightly sealed and oxygen was removed from the system through 10 repetitions of pressurization and depressurization with nitrogen gas.

The system was then heated to 75° C. and a polymerization reaction was carried out for 1 hour. Next, 10 g of tetrahydrofuran was added to the system and then the resultant solution was added dropwise to 100 g of methanol as a solvent to cause precipitation of a polymerized product. Thereafter, the polymerized product that had precipitated was collected by filtration. Note that the obtained polymerized product was a copolymer comprising 50 mol % of 1 -(4-methoxyphenyl)-1-trifluoromethyl-2,2,2-trifluoroethyl α-chloroacrylate units and 50 mol % of α-methylstyrene units.

Thereafter, various measurements were performed with respect to the obtained copolymer (pre-purification copolymer A6) in the same way as in Production Example 1. The results are shown in Table 1.

### [Purification of Polymerized Product]

The polymerized product that had been collected by filtration was subsequently dissolved in 10 g of THF and then the resultant solution was added dropwise to 100 g of a mixed solvent of THF and MeOH (THF: MeOH (mass ratio)=30:70) to cause precipitation of a white coagulated material (copolymer comprising 1-(4-methoxyphenyl)-1-trifluoromethyl-2,2,2-trifluoroethyl α-chloroacrylate units and α-methylstyrene units). The solution containing the precipitated copolymer was subsequently filtered using a Kiriyama funnel to obtain a white copolymer (copolymer comprising 50 mol % of 1-(4-methoxyphenyl)-1-trifluoromethyl-2,2,2-trifluoroethyl a -chloroacrylate units and 50 mol % of α-methylstyrene units).

Thereafter, various measurements were performed with respect to the obtained copolymer (post-purification copolymer A6) in the same way as in Production Example 1. The results are shown in Table 1.

### Production Example 7: Production of Copolymer A7

### [Synthesis of Polymerized Product]

A glass ampoule in which a stirrer had been placed was charged with 3 g of 1-phenyl-1-trifluoromethyl-2,2, 2-trifluoroethyl α-chloroacrylate (ACAFPh) as a monomer (a) and 1.066 g of α-methylstyrene as a monomer (b). In addition, 6.771 g of deionized water relative to 0.5463 g of the 18% solid content aqueous solution of partially hydrogenated tallow fatty acid potassium soap produced in Production Example 2 was added into the same ampoule to obtain a monomer composition, and then the ampoule was tightly sealed and oxygen was removed from the system through 10 repetitions of pressurization and depressurization with nitrogen gas.

The system was then heated to 40° C. and a polymerization reaction was carried out for 11 hours. Next, 10 g of tetrahydrofuran was added to the system and then the resultant solution was added dropwise to 100 g of methanol as a solvent to cause precipitation of a polymerized product. Thereafter, the polymerized product that had precipitated was collected by filtration. Note that the obtained polymerized product was a copolymer comprising 54 mol % of 1 -phenyl-1-trifluoromethyl-2,2,2-trifluoroethyl α-chloroacrylate units and 46 mol % of α-methylstyrene units.

Thereafter, various measurements were performed with respect to the obtained copolymer (pre-purification copolymer A7) in the same way as in Production Example 1. The results are shown in Table 1.

### [Purification of Polymerized Product]

The polymerized product that had been collected by filtration was subsequently dissolved in 10 g of THF and then the resultant solution was added dropwise to 100 g of a mixed solvent of THF and MeOH (THF: MeOH (mass ratio)=34:66) to cause precipitation of a white coagulated material (copolymer comprising 1-phenyl-1-trifluoromethyl-2,2,2-trifluoroethyl α-chloroacrylate units and α-methylstyrene units). The solution containing the precipitated copolymer was subsequently filtered using a Kiriyama funnel to obtain a white copolymer (copolymer comprising 54 mol % of 1-phenyl-1-trifluoromethyl-2,2,2-trifluoroethyl α-chloroacrylate units and 46 mol % of α-methylstyrene units).

Thereafter, various measurements were performed with respect to the obtained copolymer (post-purification copolymer A7) in the same way as in

Production Example 1. The results are shown in Table 1.

### PRODUCTION OF COPOLYMER B

### Production Example 8: Production of Copolymer B1

### [Synthesis of Polymerized Product]

A monomer composition containing 3 g of 2,2,3,3,3 -pentafluoropropyl α-chloroacrylate (ACAPFP) as a monomer (c), 3.476 g of α-methylstyrene as a monomer (d), 0.0055 g of azobisisobutyronitrile as a polymerization initiator, and 1.6205 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours. Thereafter, the glass vessel was restored to room temperature, the inside of the glass vessel was opened to the atmosphere, and then 10 g of THF was added to the resultant solution. The solution to which the THF had been added was then added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,3-pentafluoropropyl α-chloroacrylate units and 50 mol % of α-methylstyrene units.

Thereafter, various measurements were performed with respect to the obtained copolymer (pre-purification copolymer B1) in the same way as in Production Example 1. The results are shown in Table 2.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=15:85) to cause precipitation of a white coagulated material (copolymer comprising 2,2,3,3,3 -pentafluoropropyl α-chloroacrylate units and α-methylstyrene units). The solution containing the precipitated coagulated material was subsequently filtered using a Kiriyama funnel to obtain a white copolymer (copolymer comprising 50 mol % of 2,2,3,3,3-pentafluoropropyl α-chloroacrylate units and 50 mol % of α-methylstyrene units).

Thereafter, various measurements were performed with respect to the obtained copolymer (post-purification copolymer B1) in the same way as in Production Example 1. The results are shown in Table 2.

### Production Example 9: Production of copolymer B2

### [Synthesis of Polymerized Product]

A monomer composition containing 3 g of 2,2,3,3,3-pentafluoropropyl α-chloroacrylate (ACAPFP) as a monomer (c), 3.468 g of α-methylstyrene as a monomer (d), 0.0014 g of azobisisobutyronitrile as a polymerization initiator, and 6.4666 g of cyclopentanone as a solvent was loaded into a glass vessel. The glass vessel was tightly sealed and purged with nitrogen, and was stirred under a nitrogen atmosphere inside of a 40° C. constant-temperature tank for 50 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,3-pentafluoropropyl α-chloroacrylate units and 50 mol % of α-methylstyrene units.

Thereafter, various measurements were performed with respect to the obtained copolymer (pre-purification copolymer B2) in the same way as in Production Example 1. The results are shown in Table 2.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=26:74) to cause precipitation of a white coagulated material (polymer comprising 2,2,3,3,3-pentafluoropropyl α-chloroacrylate units and α-methylstyrene units). The solution containing the precipitated coagulated material was subsequently filtered using a Kiriyama funnel to obtain a white copolymer (copolymer comprising 50 mol % of 2,2,3, 3,3-pentafluoropropyl α-chloroacrylate units and 50 mol % of α-methylstyrene units).

Thereafter, various measurements were performed with respect to the obtained copolymer (post-purification copolymer B2) in the same way as in Production Example 1. The results are shown in Table 2.

### Production Example 10: Production of copolymer B3

### [Synthesis of Polymerized Product]

A monomer composition containing 3 g of 2,2,3,3,3-pentafluoropropyl α-chloroacrylate (ACAPFP) as a monomer (c), 3.476 g of α-methylstyrene as a monomer (d), 0.1103 g of azobisisobutyronitrile as a polymerization initiator, and 1.6205 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,3-pentafluoropropyl α-chloroacrylate units and 50 mol % of α-methylstyrene units.

Thereafter, various measurements were performed with respect to the obtained copolymer (pre-purification copolymer B3) in the same way as in Production Example 1. The results are shown in Table 2.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=5:95) to cause precipitation of a white coagulated material (copolymer comprising 2,2,3,3,3 -pentafluoropropyl α-chloroacrylate units and α-methylstyrene units). The solution containing the precipitated coagulated material was subsequently filtered using a Kiriyama funnel to obtain a white copolymer (copolymer comprising 50 mol % of 2,2,3,3,3-pentafluoropropyl α-chloroacrylate units and 50 mol % of α-methylstyrene units).

Thereafter, various measurements were performed with respect to the obtained copolymer (post-purification copolymer B3) in the same way as in Production Example 1. The results are shown in Table 2.

### Production Example 11: Production of Copolymer B4

### [Synthesis of Polymerized Product]

A monomer composition containing 3 g of 2,2,3,3,3-pentafluoropropyl α-chloroacrylate (ACAPFP) as a monomer (c), 3.476 g of α-methylstyrene as a monomer (d), 0.0005 g of azobisisobutyronitrile as a polymerization initiator, and 1.6205 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,3-pentafluoropropyl α-chloroacrylate units and 50 mol % of α-methylstyrene units.

Thereafter, various measurements were performed with respect to the obtained copolymer (pre-purification copolymer B4) in the same way as in Production Example 1. The results are shown in Table 2.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=20:80) to cause precipitation of a white coagulated material (copolymer comprising 50 mol % of 2,2,3,3,3-pentafluoropropyl α-chloroacrylate units and 50 mol % α-methylstyrene units). The solution containing the precipitated coagulated material was subsequently filtered using a Kiriyama funnel to obtain a white copolymer (polymer comprising 2,2,3,3,3-pentafluoropropyl α-chloroacrylate units and α-methylstyrene units).

Thereafter, various measurements were performed with respect to the obtained copolymer (post-purification copolymer B4) in the same way as in Production Example 1. The results are shown in Table 2.

### Production Example 12: Production of Copolymer B5

### [Synthesis of Polymerized Product]

A monomer composition containing 3 g of 2,2,3,3,3-pentafluoropropyl α-chloroacrylate (ACAPFP) as a monomer (c), 3.476 g of α-methylstyrene as a monomer (d), 0.0275 g of azobisisobutyronitrile as a polymerization initiator, and 1.6205 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,3-pentafluoropropyl α-chloroacrylate units and 50 mol % of α-methylstyrene units.

Thereafter, various measurements were performed with respect to the obtained copolymer (pre-purification copolymer B5) in the same way as in Production Example 1. The results are shown in Table 2.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=10:90) to cause precipitation of a white coagulated material (copolymer comprising 50 mol % of 2,2,3,3,3-pentafluoropropyl α-chloroacrylate units and 50 mol % of α-methylstyrene units). The solution containing the precipitated coagulated material was subsequently filtered using a Kiriyama funnel to obtain a white copolymer (polymer comprising 2,2,3,3,3-pentafluoropropyl α-chloroacrylate units and π-methylstyrene units).

Thereafter, various measurements were performed with respect to the obtained copolymer (post-purification copolymer B5) in the same way as in Production Example 1. The results are shown in Table 2.

### Production Example 13: Production of Copolymer B6

### [Synthesis of Polymerized Product]

A monomer composition containing 3 g of 2,2,3,3,3-pentafluoropropyl α-chloroacrylate (ACAPFP) as a monomer (c), 3.235 g of 4-fluoro-α-methylstyrene as a monomer (d), 0.0014 g of azobisisobutyronitrile as a polymerization initiator, and 6.4666 g of cyclopentanone as a solvent was loaded into a glass vessel. The glass vessel was tightly sealed and purged with nitrogen, and was stirred under a nitrogen atmosphere inside of a 40° C. constant-temperature tank for 50 hours. Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,3-pentafluoropropyl α-chloroacrylate units and 50 mol % of 4-fluoro-α-methylstyrene units. Thereafter, various measurements were performed with respect to the obtained copolymer (pre-purification copolymer B6) in the same way as in Production Example 1. The results are shown in Table 2.

### [Purification of Polymerized Product]

Next, the obtained polymerized product was dissolved in 100 g of THF and then the resultant solution was added dropwise to a mixed solvent of THF and MeOH (THF: MeOH (mass ratio)=25:75) to cause precipitation of a white coagulated material (copolymer comprising 2,2,3, 3, 3-pentafluoropropyl α-chloroacrylate units and 4-fluoro-α-methylstyrene units). The solution containing the precipitated coagulated material was subsequently filtered using a Kiriyama funnel to obtain a white copolymer (copolymer comprising 50 mol % of 2,2,3,3,3-pentafluoropropyl α-chloroacrylate units and 50 mol % of 4-fluoro-α-methylstyrene units).

Thereafter, various measurements were performed with respect to the obtained copolymer (post-purification copolymer B6) in the same way as in Production Example 1. The results are shown in Table 2.

### Production Example 14: Production of Copolymer B7

### [Synthesis of Polymerized Product]

A monomer composition containing 3 g of 2,2,2-trifluoroethyl α-chloroacrylate (ACATFE) as a monomer (c), 4.399 g of α-methylstyrene as a monomer (d), 0.0070 g of azobisisobutyronitrile as a polymerization initiator, and 1.8514 g of cyclopentanone as a solvent was loaded into a glass vessel. The glass vessel was tightly sealed and purged with nitrogen, and was stirred under a nitrogen atmosphere inside of a 78° C.constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,2-trifluoroethyl α-chloroacrylate units and 50 mol % of α-methylstyrene units.

Thereafter, various measurements were performed with respect to the obtained copolymer (pre-purification copolymer B7) in the same way as in Production Example 1. The results are shown in Table 2.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=15:85) to cause precipitation of a white coagulated material (copolymer comprising 50% of 2,2,2-trifluoroethyl α-chloroacrylate units and 50% of α-methylstyrene units). The solution containing the precipitated coagulated material was subsequently filtered using a Kiriyama funnel to obtain a white copolymer (copolymer comprising 50 mol % of 2,2,2-trifluoroethyl α-chloroacrylate units and 50 mol % of α-methylstyrene units).

Thereafter, various measurements were performed with respect to the obtained copolymer (post-purification copolymer B7) in the same way as in Production Example 1. The results are shown in Table 2.

### Production Example 15: Production of Copolymer B8

### [Synthesis of Polymerized Product]

A monomer composition containing 3 g of 2,2,3,3,4,4,4-heptafluorobutyl α-chloroacrylate (ACAHFB) as a monomer (c), 2.8783 g of α-methylstyrene as a monomer (d), 0.0046 g of azobisisobutyronitrile as a polymerization initiator, and 1.471 g of cyclopentanone as a solvent was loaded into a glass vessel. The glass vessel was tightly sealed and purged with nitrogen, and was stirred under a nitrogen atmosphere inside of a 40° C. constant-temperature tank for 50 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,4,4,4-heptafluorobutyl α-chloroacrylate units and 50 mol % of α-methylstyrene units.

Thereafter, various measurements were performed with respect to the obtained copolymer (pre-purification copolymer B8) in the same way as in Production Example 1. The results are shown in Table 3.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=20:80) to cause precipitation of a white coagulated material (copolymer comprising 2,2,3,3,4,4,4-heptafluorobutyl α-chloroacrylate units and α-methylstyrene units). The solution containing the precipitated coagulated material was subsequently filtered using a Kiriyama funnel to obtain a white copolymer (copolymer comprising 50 mol % of 2,2,3,3,4,4,4-heptafluorobutyl α-chloroacrylate units and 50 mol % of α-methylstyrene units).

Thereafter, various measurements were performed with respect to the obtained copolymer (post-purification copolymer B8) in the same way as in Production Example 1. The results are shown in Table 3.

### Production Example 16: Production of Copolymer B9

### [Synthesis of Polymerized Product]

A monomer composition containing 3 g of 2,2, 3,3,4,4,4-heptafluorobutyl α-chloroacrylate (ACAHFB) as a monomer (c), 2.8783 g of α-methylstyrene as a monomer (d), 0.0046 g of azobisisobutyronitrile as a polymerization initiator, and 1.471 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,4,4,4-heptafluorobutyl α-chloroacrylate units and 50 mol % of α-methylstyrene units.

Thereafter, various measurements were performed with respect to the obtained copolymer (pre-purification copolymer B9) in the same way as in Production Example 1. The results are shown in Table 3.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=10:90) to cause precipitation of a white coagulated material (copolymer comprising 50 mol % of 2,2,3,3,4,4,4-heptafluorobutyl α-chloroacrylate units and 50 mol % of α-methylstyrene units). The solution containing the precipitated coagulated material was subsequently filtered using a Kiriyama funnel to obtain a white copolymer (polymer comprising 2,2,3,3,4,4,4-heptafluorobutyl α-chloroacrylate units and α-methylstyrene units).

Thereafter, various measurements were performed with respect to the obtained copolymer (post-purification copolymer B9) in the same way as in Production Example 1. The results are shown in Table 3.

### Production Example 17: Production of Copolymer B10

### [Synthesis of Polymerized Product]

A monomer composition containing 3 g of 2,2, 3, 3,4,4,4-heptafluorobutyl α-chloroacrylate (ACAHFB) as a monomer (c), 2.8783 g of α-methylstyrene as a monomer (d), 0.0046 g of azobisisobutyronitrile as a polymerization initiator, and 1.4813 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,4,4,4-heptafluorobutyl α-chloroacrylate units and 50 mol % of α-methylstyrene units.

Thereafter, various measurements were performed with respect to the obtained copolymer (pre-purification copolymer B10) in the same way as in Production Example 1. The results are shown in Table 3.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=9:91) to cause precipitation of a white coagulated material (copolymer comprising 50 mol % of 2,2,3,3,4,4,4-heptafluorobutyl α-chloroacrylate units and 50 mol % of α-methylstyrene units). The solution containing the precipitated coagulated material was subsequently filtered using a Kiriyama funnel to obtain a white copolymer (polymer comprising 2,2,3,3,4,4,4-heptafluorobutyl α-chloroacrylate units and α-methylstyrene units).

Thereafter, various measurements were performed with respect to the obtained copolymer (post-purification copolymer B10) in the same way as in Production Example 1. The results are shown in Table 3.

### Production Example 18: Production of Copolymer B11

### [Synthesis of Polymerized Product]

A monomer composition containing 3 g of 2,2,3,3,4,4,4-heptafluorobutyl α-chloroacrylate (ACAHFB) as a monomer (c), 2.8783 g of α-methylstyrene as a monomer (d), 0.0913 g of azobisisobutyronitrile as a polymerization initiator, and 1.4927 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,4,4,4-heptafluorobutyl α-chloroacrylate units and 50 mol % of α-methylstyrene units.

Thereafter, various measurements were performed with respect to the obtained copolymer (pre-purification copolymer B11) in the same way as in Production Example 1. The results are shown in Table 3.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=7:93) to cause precipitation of a white coagulated material (copolymer comprising 50 mol % of 2,2,3,3,4,4,4-heptafluorobutyl α-chloroacrylate units and 50 mol % of α-methylstyrene units). The solution containing the precipitated coagulated material was subsequently filtered using a Kiriyama funnel to obtain a white copolymer (polymer comprising 2,2,3,3,4,4,4-heptafluorobutyl α-chloroacrylate units and α-methylstyrene units).

Thereafter, various measurements were performed with respect to the obtained copolymer (post-purification copolymer B11) in the same way as in Production Example 1. The results are shown in Table 3.

### Production Example 19: Production of Copolymer B12

### [Synthesis of Polymerized Product]

A monomer composition containing 3 g of 2,2,3,3,4,4,4-heptafluorobutyl α-chloroacrylate (ACAHFB) as a monomer (c), 2.8783 g of α-methylstyrene as a monomer (d), 0.1827 g of azobisisobutyronitrile as a polymerization initiator, and 1.5155 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,4,4,4-heptafluorobutyl α-chloroacrylate units and 50 mol % of α-methylstyrene units.

Thereafter, various measurements were performed with respect to the obtained copolymer (pre-purification copolymer B12) in the same way as in Production Example 1. The results are shown in Table 3.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=4:96) to cause precipitation of a white coagulated material (copolymer comprising 50 mol % of 2,2,3,3,4,4,4-heptafluorobutyl α-chloroacrylate units and 50 mol % of α-methylstyrene units). The solution containing the precipitated coagulated material was subsequently filtered using a Kiriyama funnel to obtain a white copolymer (polymer comprising 2,2,3,3,4,4,4-heptafluorobutyl α-chloroacrylate units and α-methylstyrene units).

Thereafter, various measurements were performed with respect to the obtained copolymer (post-purification copolymer B12) in the same way as in Production Example 1. The results are shown in Table 3.

### Production Example 20: Production of copolymer B13

### [Synthesis of Polymerized Product]

A monomer composition containing 3 g of 2,2, 3,3,4,4,4-heptafluorobutyl α-chloroacrylate (ACAHFB) as a monomer (c), 3.315 g of 4-fluoro-α-methylstyrene as a monomer (d), 0.0457 g of azobisisobutyronitrile as a polymerization initiator, and 1.5902 g of cyclopentanone as a solvent was loaded into a glass vessel. The glass vessel was tightly sealed and purged with nitrogen, and was stirred under a nitrogen atmosphere inside of a 78° C. constant-temperature tank for 6 hours.

Thereafter, the glass vessel was restored to room temperature, the inside of the glass vessel was opened to the atmosphere, and then 10 g of THF was added to the resultant solution. The solution to which the THF had been added was added dropwise to 100 g of MeOH as a solvent to cause precipitation of a polymerized product. The solution containing the polymerized product that had precipitated was subsequently filtered using a Kiriyama funnel to obtain a white coagulated material (polymerized product). Note that the obtained polymerized product was a copolymer comprising 50 mol % of 2,2,3,3,4,4,4-heptafluorobutyl α-chloroacrylate units and 50 mol % of 4-fluoro-α-methylstyrene units.

Thereafter, various measurements were performed with respect to the obtained copolymer (pre-purification copolymer B13) in the same way as in Production Example 1. The results are shown in Table 3.

### [Purification of Polymerized Product]

Next, the obtained polymerized product was dissolved in 100 g of THF and then the resultant solution was added dropwise to 100 g of a mixed solvent of THF and MeOH (THF: MeOH (mass ratio)=8:92) to cause precipitation of material (copolymer comprising 2,2,3,3,4,4,4-a white coagulated heptafluorobutyl α-chloroacrylate units and 4-fluoro-α-methylstyrene units). The solution containing the precipitated coagulated material was subsequently filtered using a Kiriyama funnel to obtain a white copolymer (copolymer comprising 50 mol % of 2,2,3,3,4,4,4-heptafluorobutyl α-chloroacrylate units and 50 mol % of 4-fluoro-α-methylstyrene units).

Thereafter, various measurements were performed with respect to the obtained copolymer (post-purification copolymer B13) in the same way as in Production Example 1. The results are shown in Table 3.

### EXAMPLE 1

### Production of Positive Resist Composition

The copolymer A1 produced as described above was dissolved in isoamyl acetate as a solvent to produce a positive resist composition (A) of 3 mass % in concentration as a positive resist composition containing only a copolymer A.

In addition, the copolymer B1 produced as described above was dissolved in isoamyl acetate as a solvent to produce a positive resist composition (B) of 3 mass % in concentration as a positive resist composition containing only a copolymer B.

Furthermore, the copolymer A1 produced as described above and the copolymer B1 produced as described above were dissolved in isoamyl acetate as a solvent such that a mass ratio of the copolymer A1 and the copolymer B1 was 99:1 to produce a positive resist composition (A/B mixed system) of 3 mass % in concentration as a positive resist composition containing a copolymer A and a copolymer B.

### γ Value

A spin coater (MS-A150 produced by Mikasa Co., Ltd.) was used to apply the positive resist composition (A/B mixed system) obtained as described above onto a silicon wafer of 4 inches in diameter such as to have a thickness of 50 nm. The applied positive resist composition (A/B mixed system) was heated for 1 minute by a hot plate having a temperature of 170° C. to form a resist film on the silicon wafer (resist film formation step). An electron beam lithography tool (ELS-S50 produced by Elionix Inc.) was used to write a plurality of patterns (dimensions: 500 μm×500 μm) over the resist film with different electron beam irradiation doses (exposure step). The resist film that had been exposed was then heated for 1 minute using a 100° C. hot plate (post exposure bake step). The resist film that had been heated was then subjected to 1 minute of development treatment at a temperature of 23° C. using isopropyl alcohol as a developer (development step). Thereafter, the developer was removed by nitrogen blowing.

Note that the electron beam irradiation dose was varied in a range of 4 μC/cm² to 200 μC/cm² in increments of 4 μC/cm². Next, an optical film thickness measurement tool (Lambda Ace produced by SCREEN Semiconductor Solutions Co., Ltd.) was used to measure the thickness of the resist film in regions in which writing had been performed. A sensitivity curve was prepared that indicated a relationship between the common logarithm of the total electron beam irradiation dose and the remaining film fraction of the resist film after development it (=thickness of resist film after development/thickness of resist film formed on silicon wafer).

With respect to the obtained sensitivity curve (horizontal axis: common logarithm of total electron beam irradiation dose; vertical axis: remaining film fraction of resist film (0≤remaining film fraction ≤1.00)), the sensitivity curve was fitted to a quadratic function in a range from a remaining film fraction of 0.20 to a remaining film fraction of 0.80. A straight line (linear approximation for gradient of sensitivity curve) was then prepared that joined points on the obtained quadratic function (function of remaining film fraction and common logarithm of total irradiation dose) corresponding to remaining film fractions of 0 and 0.50. The total electron beam irradiation dose Eth (μC/cm²) corresponding to a remaining film fraction of 0 on the obtained straight line (function of remaining film fraction and common logarithm of total irradiation dose) was determined. A smaller value for Eₜₕ indicates higher sensitivity and that the copolymers A and B used as the positive resist can undergo better scission at a low irradiation dose.

In addition, a γ value was determined using the following formula. The result is shown in Table 4. In the following formula, E₀ is the logarithm of the total irradiation dose obtained when the sensitivity curve is fitted to a quadratic function in a range from a remaining film fraction of 0.20 to a remaining film fraction of 0.80, and then a remaining film fraction of 0 is substituted with respect to the obtained quadratic function (function of remaining film fraction and common logarithm of total irradiation dose). Also, E₁ is the logarithm of the total irradiation dose obtained when a straight line is prepared that joins points on the obtained quadratic function corresponding to remaining film fractions of 0 and 0.50 (linear approximation for gradient of sensitivity curve), and then a remaining film fraction of 1.00 is substituted with respect to the obtained straight line (function of remaining film fraction and common logarithm of total irradiation dose). The following formula expresses the gradient of the straight line between a remaining film fraction of 0 and a remaining film fraction of 1.00. A larger γ value indicates that the sensitivity curve has a larger gradient and that a clear pattern can be better formed.

$$γ = {\vert {log}_{10} ( \frac{{E}_{1}}{{E}_{0}} ) \vert}^{- 1} \qquad [ Math . 1 ]$$

### Eth

A resist film was formed on a silicon wafer in the same way as in the evaluation method of the “γ value”. The initial thickness T₀ of the obtained resist film was measured using an optical film thickness measurement tool (Lambda Ace produced by SCREEN Semiconductor Solutions Co., Ltd.). The total electron beam irradiation dose Eₜₕ (μC/cm²) corresponding to a remaining film fraction of 0 on the straight line (linear approximation for gradient of sensitivity curve) obtained in calculation of the γ value was determined. The result is shown in Table 4. A smaller value for Eₜₕ indicates higher resist film sensitivity and higher resist pattern formation efficiency.

### Remaining Film Fraction (Half-Pitch (hp): 25 nm)

A spin coater (MS-A150 produced by Mikasa Co., Ltd.) was used to apply the positive resist composition (A/B mixed system) obtained as described above onto a 4 inch silicon wafer such as to have a thickness of 50 nm. The applied positive resist composition was heated for 1 minute by a hot plate having a temperature of 170° C. to form a positive resist film on the silicon wafer. An electron beam lithography tool (ELS-S50 produced by Elionix Inc.) was used to perform electron beam writing of a 1:1 line-and-space pattern having a line width of 25 nm (i.e., a half pitch of 25 nm) with an optimal exposure dose (Eₒₚ) so as to obtain an electron beam-written wafer. Note that the optimal exposure dose was set as appropriate with a value approximately double Eₜₕ as a rough guide.

The electron beam-written wafer was subjected to development treatment through 1 minute of immersion in isopropyl alcohol (IPA) as a resist developer at 23° C. Thereafter, the developer was removed by nitrogen blowing to form a line-and-space pattern (half-pitch: 25 nm). A pattern section was then cleaved and was observed at ×100,000 magnification using a scanning electron microscope (JMS-7800F PRIME produced by JEOL Ltd.) in order to measure the maximum height (Tₘₐₓ) of the resist pattern after development and the initial thickness T₀ of the resist film. The “remaining film fraction (half-pitch (hp): 25 nm)” was determined by the following formula and was then evaluated based on the following standard. The result is shown in Table 4. A higher remaining film fraction (half-pitch (hp): 25 nm) indicates less resist pattern top loss.
Remaining film fraction (%)=(Tₘₐₓ/T₀)×100
A: More than 98.5%
B: More than 96% and not more than 98.5%
C: 96% or less

### Residues

The resist pattern formed in evaluation of “Remaining film fraction” described above was observed using a scanning electron microscope (SEM) at ×100,000 magnification, and the degree to which residues remained in the resist pattern was evaluated by the following standard. The result is shown in Table 4. Note that a residue remaining in a resist pattern can be confirmed as a “dot” or the like having high brightness in an SEM image compared to a line pattern region where a residue is not attached. Fewer residues in a resist pattern indicate that the resist pattern has higher contrast.
A: Residues not observed in hp 25 nm resist pattern
B: Residues observed in hp 25 nm resist pattern in very small amount that is within permissible range
C: Residues observed in hp 25 nm resist pattern in large amount that is not within permissible range

### Dry Etching Resistance

A spin coater (MS-A150 produced by Mikasa Co., Ltd.) was used to apply the positive resist composition (A/B mixed system) obtained as described above onto a silicon wafer of 4 inches in diameter such as to have a thickness of 500 nm. The applied positive resist composition was heated for 1 minute by a hot plate having a temperature of 170° C. to form a resist film on the silicon wafer.

Next, a plasma etching apparatus (EXAM produced by Shinko Seiki Co., Ltd.) was used to perform etching of the resist film (type of gas: CF4; flow rate: 100 sccm; pressure: 10 Pa; power consumption: 200 W). Thereafter, the time taken for the film thickness to completely disappear was calculated using a step height/surface roughness/fine shape profilometer (P6 produced by KLA-Tencor). Dry etching resistance was then evaluated in accordance with the following standard. The result is shown in Table 4. Note that a longer time until the film completely disappears (etching time) indicates better dry etching resistance.
A: Time until film disappears is 4 minutes 40 seconds or more
B: Time until film disappears is not less than 4 minutes and less than 4 minutes 40 seconds
C: Time until film disappears is less than 4 minutes

### Difference Between Surface Free Energy of Copolymer A and Surface Free Energy of Copolymer B, and Surface Free Energy of Mixed System of Copolymer A and Copolymer B

The positive resist composition (A), the positive resist composition (B), and the positive resist composition (A/B mixed system) produced as described above were each used to produce a film by the following method. Next, under the following conditions, a goniometer (Drop Master 700 produced by Kyowa Interface Science Co., Ltd.) was used to measure the contact angle with respect to the obtained film for two solvents (water and diiodomethane) for which surface tension, a polar component (p), and a dispersive force component (d) were known. Surface free energy was evaluated by the Owens-Wendt method (extended Fowkes model) to calculate the surface free energy of the film.

The surface free energy of the film produced using the positive resist composition (A) was taken to be the “surface free energy of the copolymer A”, the surface free energy of the film produced using the positive resist composition (B) was taken to be the “surface free energy of the copolymer B”, and the difference between the surface free energy of the copolymer A and the surface free energy of the copolymer B (=“surface free energy of copolymer A”−“surface free energy of copolymer B”) was calculated.

Moreover, the surface free energy of the film produced using the positive resist composition (A/B mixed system) was taken to be the “surface free energy of a mixed system of the copolymer A and the copolymer B”. The results are shown in Tables 1, 2, and 4.

### Production Method of Film

A spin coater (MS-A150 produced by Mikasa Co., Ltd.) was used to apply a positive resist composition onto a silicon wafer of 4 inches in diameter such as to have a thickness of 50 nm. The applied positive resist composition was heated for 1 minute by a hot plate having a temperature of 170° C. to form a resist film on the silicon wafer.

### Measurement Conditions of Contact Angle Measurement

Needle: Metal needle 22G (water), Teflon® coated needle 22G (diiodomethane) Wait time: 1,000 ms

Liquid volume: 1.8 μL

Liquid landing recognition: Water 50 dat, diiodomethane 100 dat

Temperature: 23° C.

### EXAMPLES 2 to 64

Positive resist compositions were produced in the same way as in Example 1 with the exception that the types of copolymers A and B and the mass ratio of copolymers A and B were changed as indicated in Tables 4 to 9.

The obtained positive resist compositions were used to perform various measurements and evaluations in the same way as in Example 1. The results are shown in Tables 4 to 9.

### EXAMPLES 65 to 67

Resist films were formed in the same way as in Example 1 with the exception that the type of copolymer A and the mass ratio of copolymers A and B were changed as indicated in Table 9 and that the post exposure bake step was not performed.

The obtained resist films were used to perform various measurements and evaluations in the same way as in Example 1. The results are shown in Table 9.

### EXAMPLES 68 to 84

Positive resist compositions were produced in the same way as in Example 1 with the exception that the types of copolymers A and B and the mass ratio of copolymers A and B were changed as indicated in Table 10 and that ethanol (EtOH) was used instead of isopropyl alcohol as a developer.

The obtained positive resist compositions were used to perform various measurements and evaluations in the same way as in Example 1. The results are shown in Table 10.

### EXAMPLES 85 to 93

Positive resist compositions were produced in the same way as in Example 1 with the exception that the types of copolymers A and B, the mass ratio of copolymers A and B, and the developer were changed as indicated in Table 11.

The obtained positive resist compositions were used to perform various measurements and evaluations in the same way as in Example 1. The results are shown in Table 11.

### COMPARATIVE EXAMPLES 1 to 18

Positive resist compositions were produced in the same way as in Example 1 with the exception that the types of copolymers A and B and the mass ratio of copolymers A and B were changed as indicated in Table 12. The obtained positive resist compositions were used to perform various measurements and evaluations in the same way as in Example 1. The results are shown in Table 12.

### COMPARATIVE EXAMPLES 19 to 24

Positive resist compositions were produced in the same way as in Example 1 with the exception that a copolymer A was not used and that the developer was changed as indicated in Table 13.

The obtained positive resist compositions were used to perform various measurements and evaluations in the same way as in Example 1. The results are shown in Table 13.

In the tables:
“ACAFPh” indicates 1-phenyl-1-trifluoromethyl-2,2,2-trifluoroethyl α-chloroacrylate;
“ACAFPhOMe” indicates 1-(4-methoxyphenyl)-1-trifluoromethyl-2,2,2-trifluoroethyl α-chloroacrylate;
“KORR (18%) soap” indicates 18% solid content aqueous solution of partially hydrogenated tallow fatty acid potassium soap;
“ACAPFP” indicates 2,2,3,3,3-pentafluoropropyl α-chloroacrylate;
“ACAHFB” indicates 2,2,3,3,4,4,4-heptafluorobutyl α-chloroacrylate;
“ACATFE” indicates 2,2,2-trifluoroethyl α-chloroacrylate;
“IPA” indicates isopropyl alcohol;
“EtOH” indicates ethanol;
“PrOH” indicates 1-propanol; and
“ButOH” indicates 1-butanol.

TABLE 1

| Type of copolymer A | | A1 | A2 | A3 | A4 |
|---|---|---|---|---|---|
| Polymerization method | | Solution | Emulsion | Solution | Emulsion |
| | | polymerization | polymerization | polymerization | polymerization |
| Monomer (a) | ACAFPh [g] | 3 | 3 | 3 | 3 |
| | ACAFPhOMe [g] | — | — | — | — |
| Monomer (b) | α-Methylstyrene [g] | 2.493 | 2.712 | 1.066 | 1.066 |
| Solvent | Cyclopentanone [g] | 2.833 | — | 1.743 | — |
| | KORR (18%) soap [g] | — | 0.5463 | — | 0.5463 |
| | Deionized water [g] | — | 6.771 | — | 6.771 |
| Reaction conditions | Time [hr] | 80 | 11 | 50 | 1 |
| | Temperature [° C.] | 30 | 40 | 30 | 75 |
| Physical properties of | Number-average molecular weight (Mn) [—] | 81958 | 84269 | 82290 | 147149 |
| copolymer A before | Weight-average molecular weight (Mw) [—] | 166769 | 235343 | 165934 | 228370 |
| purification | Molecular weight distribution (Mw/Mn) [—] | 2.035 | 2.793 | 2.016 | 1.552 |
| Solvent used in precipitation of | THF:MeOH [mass ratio] | 0:100 | 0:100 | 0:100 | 30:70 |
| polymerized product | | | | | |
| Solvent used in purification of | THF:MeOH [mass ratio] | 29:71 | 35:65 | 30:70 | 34:66 |
| polymerized product | | | | | |
| Physical properties of | Number-average molecular weight (Mn) [—] | 116305 | 287802 | 125207 | 259380 |
| copolymer A after purification | Weight-average molecular weight (Mw) [—] | 186495 | 481316 | 188134 | 382253 |
| | Molecular weight distribution (Mw/Mn) [—] | 1.603 | 1.672 | 1.503 | 1.474 |
| | Surface free energy [mJ/m²] | 32.6 | 32.6 | 31 | 31 |

| Type of copolymer A | | A5 | A6 | A7 |
|---|---|---|---|---|
| Polymerization method | | Emulsion | Emulsion | Emulsion |
| | | polymerization | polymerization | polymerization |
| Monomer (a) | ACAFPh [g] | 3 | — | 3 |
| | ACAFPhOMe [g] | — | 3 | — |
| Monomer (b) | α-Methylstyrene [g] | 1.066 | 2.487 | 1.066 |
| Solvent | Cyclopentanone [g] | — | — | — |
| | KORR (18%) soap [g] | 0.5463 | 0.5463 | 0.5463 |
| | Deionized water [g] | 6.771 | 6.771 | 6.771 |
| Reaction conditions | Time [hr] | 1 | 1 | 11 |
| | Temperature [° C.] | 75 | 75 | 40 |
| Physical properties of | Number-average molecular weight (Mn) [—] | 217154 | 110394 | 141020 |
| copolymer A before | Weight-average molecular weight (Mw) [—] | 309236 | 210394 | 340282 |
| purification | Molecular weight distribution (Mw/Mn) [—] | 1.424 | 1.906 | 2.413 |
| Solvent used in precipitation of | THF:MeOH [mass ratio] | 33:67 | 0:100 | 0:100 |
| polymerized product | | | | |
| Solvent used in purification of | THF:MeOH [mass ratio] | 33:67 | 30:70 | 34:66 |
| polymerized product | | | | |
| Physical properties of | Number-average molecular weight (Mn) [—] | 267588 | 149583 | 246433 |
| copolymer A after purification | Weight-average molecular weight (Mw) [—] | 363867 | 221293 | 395859 |
| | Molecular weight distribution (Mw/Mn) [—] | 1.360 | 1.479 | 1.606 |
| | Surface free energy [mJ/m²] | 31 | 33.1 | 31 |

TABLE 2

| Type of copolymer B | | B1 | B2 | B3 | B4 |
|---|---|---|---|---|---|
| Polymerization method | | Solution | Solution | Solution | Solution |
| | | polymerization | polymerization | polymerization | polymerization |
| Monomer (c) | ACAPFP [g] | 3 | 3 | 3 | 3 |
| | ACAHFB [g] | — | — | — | — |
| | ACATFE [g] | — | — | — | — |
| Monomer (d) | α-Methylstyrene [g] | 3.476 | 3.468 | 3.476 | 3.476 |
| | 4-Fluoro-α-methylstyrene [g] | — | — | — | — |
| Polymerization initiator | Azobisisobutyronitrile [g] | 0.0055 | 0.0014 | 0.1103 | 0.0005 |
| Solvent | Cyclopentanone [g] | 1.6205 | 6.4666 | 1.6205 | 1.6205 |
| Reaction conditions | Time [hr] | 6 | 50 | 6 | 2 |
| | Temperature [° C.] | 78 | 40 | 78 | 78 |
| Physical properties of | Number-average molecular weight (Mn) [—] | 25718 | 68797 | 10212 | 37652 |
| copolymer B before purification | Weight-average molecular weight (Mw) [—] | 43834 | 139176 | 15605 | 69166 |
| | Molecular weight distribution (Mw/Mn) [—] | 1.704 | 2.023 | 1.528 | 1.837 |
| Solvent used in precipitation of | MeOH [g] | 100 | 100 | 100 | 100 |
| polymerized product | | | | | |
| Solvent used in purification of | Mixed solvent (THF:MeOH mass ratio) [—] | 15:85 | 26:74 | 5:95 | 20:80 |
| polymerized product | | | | | |
| Physical properties of | Number-average molecular weight (Mn) [—] | 35806 | 128728 | 13430 | 57063 |
| copolymer B after purification | Weight-average molecular weight (Mw) [—] | 49556 | 180605 | 16049 | 82912 |
| | Molecular weight distribution (Mw/Mn) [—] | 1.384 | 1.403 | 1.195 | 1.453 |
| | Surface free energy [mJ/m²] | 24.2 | 24.2 | 24.2 | 24.2 |

| Type of copolymer B | | B5 | B6 | B7 |
|---|---|---|---|---|
| Polymerization method | | Solution | Solution | Solution |
| | | polymerization | polymerization | polymerization |
| Monomer (c) | ACAPFP [g] | 3 | 3 | — |
| | ACAHFB [g] | — | — | — |
| | ACATFE [g] | — | — | 3 |
| Monomer (d) | α-Methylstyrene [g] | 3.476 | — | 4.399 |
| | 4-Fluoro-α-methylstyrene [g] | — | 3.235 | — |
| Polymerization initiator | Azobisisobutyronitrile [g] | 0.0275 | 0.0014 | 0.0070 |
| Solvent | Cyclopentanone [g] | 1.6205 | 6.4666 | 1.8514 |
| Reaction conditions | Time [hr] | 6 | 50 | 6 |
| | Temperature [° C.] | 78 | 40 | 78 |
| Physical properties of | Number-average molecular weight (Mn) [—] | 20192 | 65456 | 31303 |
| copolymer B before purification | Weight-average molecular weight (Mw) [—] | 32493 | 128473 | 50883 |
| | Molecular weight distribution (Mw/Mn) [—] | 1.609 | 1.963 | 1.625 |
| Solvent used in precipitation of | MeOH [g] | 100 | 100 | 100 |
| polymerized product | | | | |
| Solvent used in purification of | Mixed solvent (THF:MeOH mass ratio) [—] | 10:90 | 25:75 | 15:85 |
| polymerized product | | | | |
| Physical properties of | Number-average molecular weight (Mn) [—] | 27469 | 121321 | 46824 |
| copolymer B after purification | Weight-average molecular weight (Mw) [—] | 36039 | 172234 | 64383 |
| | Molecular weight distribution (Mw/Mn) [—] | 1.312 | 1.420 | 1.375 |
| | Surface free energy [mJ/m²] | 24.2 | 22.2 | 29.8 |

TABLE 3

| Type of copolymer B | | B8 | B9 | B10 |
|---|---|---|---|---|
| Polymerization method | | Solution | Solution | Solution |
| | | polymerization | polymerization | polymerization |
| Monomer (c) | ACAPFP [g] | — | — | — |
| | ACAHFB [g] | 3 | 3 | 3 |
| | ACATFE [g] | — | — | — |
| Monomer (d) | α-Methylstyrene [g] | 2.8783 | 2.8783 | 2.8783 |
| | 4-Fluoro-α-methylstyrene [g] | — | — | — |
| Polymerization initiator | Azobisisobutyronitrile [g] | 0.0046 | 0.0046 | 0.0046 |
| Solvent | Cyclopentanone [g] | 1.471 | 1.471 | 1.4813 |
| Reaction conditions | Time [hr] | 50 | 6 | 6 |
| | Temperature [° C.] | 40 | 78 | 78 |
| Physical properties of | Number-average molecular weight (Mn) [—] | 72912 | 33687 | 16042 |
| copolymer B before | Weight-average molecular weight (Mw) [—] | 140192 | 54546 | 24501 |
| purification | Molecular weight distribution (Mw/Mn) [—] | 1.923 | 1.619 | 1.527 |
| Solvent used in precipitation of | MeOH [g] | 100 | 100 | 100 |
| polymerized product | | | | |
| Solvent used in purification of | Mixed solvent (THF:MeOH mass ratio) [—] | 20:80 | 10:90 | 9:91 |
| polymerized product | | | | |
| Physical properties of | Number-average molecular weight (Mn) [—] | 112402 | 35146 | 18461 |
| copolymer B after purification | Weight-average molecular weight (Mw) [—] | 170694 | 54887 | 25273 |
| | Molecular weight distribution (Mw/Mn) [—] | 1.519 | 1.562 | 1.369 |
| | Surface free energy [mJ/m²] | 21.2 | 21.2 | 21.2 |
| Type of copolymer B | | B11 | B12 | B13 |
| Polymerization method | | Solution | Solution | Solution |
| | | polymerization | polymerization | polymerization |
| Monomer (c) | ACAPFP [g] | — | — | — |
| | ACAHFB [g] | 3 | 3 | 3 |
| | ACATFE [g] | — | — | — |
| Monomer (d) | α-Methylstyrene [g] | 2.8783 | 2.8783 | — |
| | 4-Fluoro-α-methylstyrene [g] | — | — | 3.315 |
| Polymerization initiator | Azobisisobutyronitrile [g] | 0.0913 | 0.1827 | 0.0457 |
| Solvent | Cyclopentanone [g] | 1.4927 | 1.5155 | 1.5902 |
| Reaction conditions | Time [hr] | 6 | 6 | 6 |
| | Temperature [° C.] | 78 | 78 | 78 |
| Physical properties of | Number-average molecular weight (Mn) [—] | 10875 | 12028 | 15695 |
| copolymer B before | Weight-average molecular weight (Mw) [—] | 17760 | 15500 | 23506 |
| purification | Molecular weight distribution (Mw/Mn) [—] | 1.633 | 1.289 | 1.498 |
| Solvent used in precipitation of | MeOH [g] | 100 | 100 | 100 |
| polymerized product | | | | |
| Solvent used in purification of | Mixed solvent (THF:MeOH mass ratio) [—] | 7:93 | 4:96 | 8:92 |
| polymerized product | | | | |
| Physical properties of | Number-average molecular weight (Mn) [—] | 14853 | 12028 | 17594 |
| copolymer B after purification | Weight-average molecular weight (Mw) [—] | 19958 | 15500 | 24356 |
| | Molecular weight distribution (Mw/Mn) [—] | 1.344 | 1.289 | 1.384 |
| | Surface free energy [mJ/m²] | 21.2 | 21.2 | 20.4 |

TABLE 4

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 1 | A1 | B1 | 99:1 | 8.4 | 100 | 1 | IPA |
| 2 | A1 | B1 | 95:5 | 8.4 | 100 | 1 | IPA |
| 3 | A1 | B1 | 90:10 | 8.4 | 100 | 1 | IPA |
| 4 | A1 | B1 | 80:20 | 8.4 | 100 | 1 | IPA |
| 5 | A1 | B1 | 70:30 | 8.4 | 100 | 1 | IPA |
| 6 | A1 | B2 | 99:1 | 8.4 | 100 | 1 | IPA |
| 7 | A1 | B2 | 95:5 | 8.4 | 100 | 1 | IPA |
| 8 | A1 | B5 | 99:1 | 8.4 | 100 | 1 | IPA |
| 9 | A1 | B5 | 95:5 | 8.4 | 100 | 1 | IPA |
| 10 | A1 | B5 | 90:10 | 8.4 | 100 | 1 | IPA |
| 11 | A1 | B5 | 80:20 | 8.4 | 100 | 1 | IPA |
| 12 | A1 | B5 | 70:30 | 8.4 | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 1 | 95.71 | 11.21 | A | A | A | 25.8 |
| 2 | 95.73 | 14.03 | A | A | A | 24.4 |
| 3 | 96.50 | 14.39 | A | A | A | 24.2 |
| 4 | 98.97 | 18.70 | A | A | A | 24.2 |
| 5 | 113.44 | 19.37 | A | B | B | 24.2 |
| 6 | 95.71 | 11.55 | A | A | A | 25.8 |
| 7 | 95.73 | 14.75 | A | A | A | 24.4 |
| 8 | 95.69 | 11.19 | A | A | A | 25.8 |
| 9 | 95.70 | 14.00 | A | A | A | 24.4 |
| 10 | 96.50 | 14.36 | A | A | A | 24.2 |
| 11 | 98.97 | 18.66 | A | A | A | 24.2 |
| 12 | 104.31 | 19.21 | A | A | B | 24.2 |

TABLE 5

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 13 | A2 | B1 | 99:1 | 8.4 | 100 | 1 | IPA |
| 14 | A2 | B1 | 95:5 | 8.4 | 100 | 1 | IPA |
| 15 | A2 | B1 | 90:10 | 8.4 | 100 | 1 | IPA |
| 16 | A2 | B1 | 80:20 | 8.4 | 100 | 1 | IPA |
| 17 | A2 | B1 | 70:30 | 8.4 | 100 | 1 | IPA |
| 18 | A2 | B2 | 99:1 | 8.4 | 100 | 1 | IPA |
| 19 | A2 | B2 | 95:5 | 8.4 | 100 | 1 | IPA |
| 20 | A2 | B5 | 99:1 | 8.4 | 100 | 1 | IPA |
| 21 | A2 | B5 | 95:5 | 8.4 | 100 | 1 | IPA |
| 22 | A2 | B5 | 90:10 | 8.4 | 100 | 1 | IPA |
| 23 | A2 | B5 | 80:20 | 8.4 | 100 | 1 | IPA |
| 24 | A2 | B5 | 70:30 | 8.4 | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 13 | 98.67 | 11.54 | A | A | A | 25.8 |
| 14 | 98.69 | 14.46 | A | A | A | 24.4 |
| 15 | 98.81 | 14.84 | A | A | A | 24.2 |
| 16 | 99.97 | 19.28 | A | A | A | 24.2 |
| 17 | 114.59 | 19.97 | A | B | B | 24.2 |
| 18 | 98.67 | 11.89 | A | A | A | 25.8 |
| 19 | 98.69 | 15.21 | A | A | A | 24.4 |
| 20 | 98.56 | 11.52 | A | A | A | 25.8 |
| 21 | 98.65 | 14.43 | A | A | A | 24.4 |
| 22 | 98.76 | 14.81 | A | A | A | 24.2 |
| 23 | 100.10 | 19.24 | A | A | A | 24.2 |
| 24 | 104.65 | 19.93 | A | A | B | 24.2 |

TABLE 6

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 25 | A3 | B1 | 99:1 | 6.8 | 100 | 1 | IPA |
| 26 | A3 | B1 | 95:5 | 6.8 | 100 | 1 | IPA |
| 27 | A3 | B1 | 90:10 | 6.8 | 100 | 1 | IPA |
| 28 | A3 | B1 | 80:20 | 6.8 | 100 | 1 | IPA |
| 29 | A3 | B1 | 70:30 | 6.8 | 100 | 1 | IPA |
| 30 | A3 | B2 | 99:1 | 6.8 | 100 | 1 | IPA |
| 31 | A3 | B2 | 95:5 | 6.8 | 100 | 1 | IPA |
| 32 | A3 | B5 | 99:1 | 6.8 | 100 | 1 | IPA |
| 33 | A3 | B5 | 95:5 | 6.8 | 100 | 1 | IPA |
| 34 | A3 | B5 | 90:10 | 6.8 | 100 | 1 | IPA |
| 35 | A3 | B5 | 80:20 | 6.8 | 100 | 1 | IPA |
| 36 | A3 | B5 | 70:30 | 6.8 | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 25 | 93.82 | 11.04 | A | A | A | 25.8 |
| 26 | 93.85 | 14.62 | A | A | A | 24.4 |
| 27 | 93.63 | 15.00 | A | A | A | 24.2 |
| 28 | 96.52 | 19.49 | A | A | A | 24.2 |
| 29 | 110.63 | 20.19 | A | B | B | 24.2 |
| 30 | 93.82 | 11.57 | A | A | A | 25.5 |
| 31 | 93.85 | 15.38 | A | A | A | 24.3 |
| 32 | 92.91 | 11.02 | A | A | A | 25.8 |
| 33 | 92.97 | 14.59 | A | A | A | 24.4 |
| 34 | 93.23 | 14.97 | A | A | A | 24.2 |
| 35 | 95.43 | 19.45 | A | A | A | 24.2 |
| 36 | 102.10 | 20.15 | A | A | B | 24.2 |

TABLE 7

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 37 | A4 | B1 | 99:1 | 6.8 | 100 | 1 | IPA |
| 38 | A4 | B1 | 95:5 | 6.8 | 100 | 1 | IPA |
| 39 | A4 | B1 | 90:10 | 6.8 | 100 | 1 | IPA |
| 40 | A4 | B1 | 80:20 | 6.8 | 100 | 1 | IPA |
| 41 | A4 | B1 | 70:30 | 6.8 | 100 | 1 | IPA |
| 42 | A4 | B2 | 99:1 | 6.8 | 100 | 1 | IPA |
| 43 | A4 | B2 | 95:5 | 6.8 | 100 | 1 | IPA |
| 44 | A4 | B5 | 99:1 | 6.8 | 100 | 1 | IPA |
| 45 | A4 | B5 | 95:5 | 6.8 | 100 | 1 | IPA |
| 46 | A4 | B5 | 90:10 | 6.8 | 100 | 1 | IPA |
| 47 | A4 | B5 | 80:20 | 6.8 | 100 | 1 | IPA |
| 48 | A4 | B5 | 70:30 | 6.8 | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 37 | 97.70 | 11.45 | A | A | A | 25.5 |
| 38 | 97.72 | 15.22 | A | A | A | 24.3 |
| 39 | 97.84 | 15.62 | A | A | A | 24.2 |
| 40 | 98.98 | 20.29 | A | A | A | 24.2 |
| 41 | 113.45 | 21.02 | A | B | B | 24.2 |
| 42 | 97.70 | 11.80 | A | A | A | 25.5 |
| 43 | 97.72 | 16.01 | A | A | A | 24.3 |
| 44 | 97.60 | 11.43 | A | A | A | 25.5 |
| 45 | 97.69 | 15.19 | A | A | A | 24.3 |
| 46 | 97.70 | 15.59 | A | A | A | 24.2 |
| 47 | 99.01 | 20.25 | A | A | A | 24.2 |
| 48 | 103.42 | 20.98 | A | A | B | 24.2 |

TABLE 8

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 49 | A5 | B3 | 80:20 | 6.8 | 100 | 1 | IPA |
| 50 | A5 | B3 | 70:30 | 6.8 | 100 | 1 | IPA |
| 51 | A5 | B1 | 99:1 | 6.8 | 100 | 1 | IPA |
| 52 | A5 | B1 | 95:5 | 6.8 | 100 | 1 | IPA |
| 53 | A5 | B1 | 90:10 | 6.8 | 100 | 1 | IPA |
| 54 | A5 | B1 | 80:20 | 6.8 | 100 | 1 | IPA |
| 55 | A5 | B1 | 70:30 | 6.8 | 100 | 1 | IPA |
| 56 | A5 | B4 | 99:1 | 6.8 | 100 | 1 | IPA |
| 57 | A5 | B4 | 95:5 | 6.8 | 100 | 1 | IPA |
| 58 | A5 | B4 | 90:10 | 6.8 | 100 | 1 | IPA |
| 59 | A5 | B4 | 80:20 | 6.8 | 100 | 1 | IPA |
| 60 | A5 | B4 | 70:30 | 6.8 | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 49 | 98.98 | 11.54 | A | A | B | 24.2 |
| 50 | 100.32 | 15.40 | A | A | B | 24.2 |
| 51 | 96.71 | 11.66 | A | A | A | 25.5 |
| 52 | 96.75 | 15.51 | A | A | A | 24.3 |
| 53 | 97.12 | 16.17 | A | A | A | 24.2 |
| 54 | 94.25 | 20.50 | A | A | A | 24.2 |
| 55 | 108.31 | 22.64 | A | B | B | 24.2 |
| 56 | 96.71 | 11.77 | A | A | A | 25.5 |
| 57 | 96.75 | 15.99 | A | A | A | 24.3 |
| 58 | 96.81 | 16.67 | A | A | A | 24.2 |
| 59 | 97.16 | 21.13 | A | A | A | 24.2 |
| 60 | 111.66 | 23.34 | A | B | B | 24.2 |

TABLE 9

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 61 | A5 | B6 | 80:20 | 8.8 | 100 | 1 | IPA |
| 62 | A5 | B6 | 70:30 | 8.8 | 100 | 1 | IPA |
| 63 | A6 | B6 | 80:20 | 11.1 | 100 | 1 | IPA |
| 64 | A6 | B6 | 70:30 | 11.1 | 100 | 1 | IPA |
| 65 | A5 | B1 | 90:10 | 6.8 | — | — | IPA |
| 66 | A5 | B1 | 80:20 | 6.8 | — | — | IPA |
| 67 | A5 | B1 | 70:30 | 6.8 | — | — | IPA |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 61 | 99.14 | 21.56 | A | B | B | 24.2 |
| 62 | 113.94 | 23.82 | A | B | B | 24.2 |
| 63 | 99.43 | 12.54 | A | B | B | 22.2 |
| 64 | 116.54 | 14.32 | A | B | B | 22.2 |
| 65 | 84.82 | 12.39 | A | A | A | 24.2 |
| 66 | 85.12 | 18.92 | A | A | A | 24.2 |
| 67 | 95.03 | 20.17 | A | B | B | 24.2 |

TABLE 10

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 68 | A5 | B1 | 99:1 | 6.8 | 100 | 1 | EtOH |
| 69 | A5 | B1 | 95:5 | 6.8 | 100 | 1 | EtOH |
| 70 | A5 | B1 | 90:10 | 6.8 | 100 | 1 | EtOH |
| 71 | A5 | B1 | 80:20 | 6.8 | 100 | 1 | EtOH |
| 72 | A5 | B1 | 70:30 | 6.8 | 100 | 1 | EtOH |
| 73 | A5 | B4 | 99:1 | 6.8 | 100 | 1 | EtOH |
| 74 | A5 | B4 | 95:5 | 6.8 | 100 | 1 | EtOH |
| 75 | A5 | B4 | 90:10 | 6.8 | 100 | 1 | EtOH |
| 76 | A5 | B4 | 80:20 | 6.8 | 100 | 1 | EtOH |
| 77 | A5 | B4 | 70:30 | 6.8 | 100 | 1 | EtOH |
| 78 | A5 | B5 | 99:1 | 6.8 | 100 | 1 | EtOH |
| 79 | A5 | B5 | 95:5 | 6.8 | 100 | 1 | EtOH |
| 80 | A5 | B5 | 90:10 | 6.8 | 100 | 1 | EtOH |
| 81 | A5 | B5 | 80:20 | 6.8 | 100 | 1 | EtOH |
| 82 | A5 | B5 | 70:30 | 6.8 | 100 | 1 | EtOH |
| 83 | A5 | B6 | 80:20 | 8.8 | 100 | 1 | EtOH |
| 84 | A5 | B6 | 70:30 | 8.8 | 100 | 1 | EtOH |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 68 | 46.71 | 10.44 | A | A | A | 25.5 |
| 69 | 46.76 | 13.29 | A | A | A | 24.3 |
| 70 | 49.54 | 13.29 | A | A | A | 24.2 |
| 71 | 51.23 | 13.73 | A | A | A | 24.2 |
| 72 | 60.32 | 18.28 | A | B | B | 24.2 |
| 73 | 46.71 | 10.55 | A | A | A | 25.5 |
| 74 | 46.76 | 13.70 | A | A | A | 24.3 |
| 75 | 49.54 | 13.70 | A | A | A | 24.2 |
| 76 | 52.34 | 14.16 | A | A | A | 24.2 |
| 77 | 62.18 | 18.85 | A | B | B | 24.2 |
| 78 | 46.70 | 10.42 | A | A | A | 25.5 |
| 79 | 46.77 | 13.26 | A | A | A | 24.3 |
| 80 | 48.98 | 13.26 | A | A | A | 24.2 |
| 81 | 48.99 | 13.70 | A | A | A | 24.2 |
| 82 | 53.21 | 18.25 | A | A | B | 24.2 |
| 83 | 50.52 | 14.44 | A | B | B | 22.2 |
| 84 | 63.45 | 19.23 | A | B | B | 22.2 |

TABLE 11

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| | A | B | (mass ratio) | copolymer B | temperature | time | Developer |
| Example | Type | Type | [—] | [mJ/m²] | [° C.] | [min] | Type |
| 85 | A5 | B8 | 80:20 | 9.8 | 100 | 1 | IPA |
| 86 | A5 | B9 | 80:20 | 9.8 | 100 | 1 | IPA |
| 87 | A5 | B10 | 80:20 | 9.8 | 100 | 1 | IPA |
| 88 | A5 | B10 | 80:20 | 9.8 | 100 | 1 | EtOH |
| 89 | A5 | B10 | 80:20 | 9.8 | 100 | 1 | PrOH |
| 90 | A5 | B10 | 80:20 | 9.8 | 100 | 1 | ButOH |
| 91 | A5 | B11 | 80:20 | 9.8 | 100 | 1 | IPA |
| 92 | A5 | B12 | 80:20 | 9.8 | 100 | 1 | IPA |
| 93 | A5 | B13 | 80:20 | 10.6 | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| | Eₜₕ | γ value | film | | etching | copolymer B |
| Example | [μC/cm²] | [—] | fraction | Residues | resistance | [mJ/m²] |
| 85 | 90.12 | 15.94 | A | B | A | 21.2 |
| 86 | 84.01 | 15.9 | A | B | A | 21.2 |
| 87 | 76.23 | 13.64 | A | B | A | 21.2 |
| 88 | 49.94 | 13.19 | A | B | A | 21.2 |
| 89 | 63.45 | 13.48 | A | B | A | 21.2 |
| 90 | 81.66 | 13.54 | A | B | A | 21.2 |
| 91 | 74.52 | 11.33 | A | B | A | 21.2 |
| 92 | 68.87 | 12.56 | A | B | A | 21.2 |
| 93 | 74.56 | 13.38 | A | B | B | 21.2 |

TABLE 12

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| Comparative | A | B | (mass ratio) | copolymer B | temperature | time | Developer |
| Example | Type | Type | [—] | [mJ/m²] | [° C.] | [min] | Type |
| 1 | — | B3 | 0:100 | — | 100 | 1 | IPA |
| 2 | — | B1 | 0:100 | — | 100 | 1 | IPA |
| 3 | — | B4 | 0:100 | — | 100 | 1 | IPA |
| 4 | — | B2 | 0:100 | — | 100 | 1 | EtOH |
| 5 | — | B5 | 0:100 | — | 100 | 1 | IPA |
| 6 | — | B7 | 0:100 | — | 100 | 1 | IPA |
| 7 | A1 | — | 100:0 | — | 100 | 1 | IPA |
| 8 | A1 | B7 | 95:5 | 2.8 | 100 | 1 | IPA |
| 9 | A2 | — | 100:0 | — | 100 | 1 | IPA |
| 10 | A2 | B7 | 95:5 | 2.8 | 100 | 1 | IPA |
| 11 | A3 | — | 100:0 | — | 100 | 1 | IPA |
| 12 | A3 | B7 | 95:5 | 1.2 | 100 | 1 | IPA |
| 13 | A4 | — | 100:0 | — | 100 | 1 | IPA |
| 14 | A4 | B7 | 95:5 | 1.2 | 100 | 1 | IPA |
| 15 | A5 | — | 100:0 | — | 100 | 1 | IPA |
| 16 | A5 | B7 | 95:5 | 1.2 | 100 | 1 | IPA |
| 17 | A7 | — | 100:0 | — | 100 | 1 | IPA |
| 18 | A7 | B7 | 95:5 | 1.2 | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| Comparative | Eₜₕ | γ value | film | | etching | copolymer B |
| Example | [μC/cm²] | [—] | fraction | Residues | resistance | [mJ/m²] |
| 1 | 100.41 | 5.65 | C | C | C | 24.2 |
| 2 | 147.46 | 7.41 | C | C | C | 24.2 |
| 3 | 148.95 | 7.49 | C | C | C | 24.2 |
| 4 | 112.48 | 4.89 | C | C | C | 24.2 |
| 5 | 131.12 | 6.91 | C | C | C | 24.2 |
| 6 | 153.46 | 7.54 | C | B | C | 29.8 |
| 7 | 95.49 | 8.35 | B | A | A | 32.6 |
| 8 | 99.31 | 7.93 | C | C | A | 32.1 |
| 9 | 98.03 | 8.95 | B | A | A | 32.6 |
| 10 | 101.95 | 8.50 | C | C | A | 32.1 |
| 11 | 93.21 | 9.05 | B | A | A | 31 |
| 12 | 96.94 | 8.60 | C | C | A | 30.5 |
| 13 | 97.06 | 9.42 | B | A | A | 31 |
| 14 | 100.94 | 8.95 | C | C | A | 30.5 |
| 15 | 96.10 | 9.52 | B | A | A | 31 |
| 16 | 99.94 | 9.04 | C | C | A | 30.5 |
| 17 | 97.06 | 9.33 | B | A | A | 31 |
| 18 | 100.94 | 8.86 | C | C | A | 30.5 |

TABLE 13

| | | | Copolymer | Difference between surface | Post exposure | | |
|---|---|---|---|---|---|---|---|
| | | | A:Copolymer | free energy of copolymer A | bake step | | |
| | Copolymer | Copolymer | B | and surface free energy of | Heating | Heating | |
| Comparative | A | B | (mass ratio) | copolymer B | temperature | time | Developer |
| Example | Type | Type | [—] | [mJ/m²] | [° C.] | [min] | Type |
| 19 | — | B8 | 0:100 | — | 100 | 1 | IPA |
| 20 | — | B9 | 0:100 | — | 100 | 1 | IPA |
| 21 | — | B10 | 0:100 | — | 100 | 1 | IPA |
| 22 | — | B11 | 0:100 | — | 100 | 1 | IPA |
| 23 | — | B12 | 0:100 | — | 100 | 1 | IPA |
| 24 | — | B13 | 0:100 | — | 100 | 1 | IPA |

| | Measurement and evaluation | | | | | |
|---|---|---|---|---|---|---|
| | | | | | | Surface free energy of mixed |
| | | | Remaining | | Dry | system of copolymer A and |
| Comparative | Eₜₕ | γ value | film | | etching | copolymer B |
| Example | [μC/cm²] | [—] | fraction | Residues | resistance | [mJ/m²] |
| 19 | 321.23 | 1.43 | C | C | C | 21.2 |
| 20 | 289.87 | 1.73 | C | C | C | 21.2 |
| 21 | 138.37 | 4.89 | C | B | C | 21.2 |
| 22 | 142.51 | 5.57 | C | B | C | 21.2 |
| 23 | 140.26 | 3.38 | C | B | C | 21.2 |
| 24 | 137.21 | 3.39 | C | B | C | 21.2 |

It can be seen from Tables 4 to 11 that a resist pattern having little resist pattern top loss and high contrast could be formed in Examples 1 to 93 in which a specific positive resist composition containing a copolymer A and a copolymer B was used as a positive resist composition.

In contrast, it can be seen that a resist pattern having little resist pattern top loss and high contrast could not be formed in a case in which a positive resist composition containing only one of a copolymer A and a copolymer B was used (Comparative Examples 1 to 5, 7, 9, 11, 13, 15, 17, and 19 to 24) and in a case in which a specific polymer was not used as a copolymer B (Comparative Examples 6, 8, 10, 12, 14, 16, and 18).

### INDUSTRIAL APPLICABILITY

According to the present disclosure, it is possible to provide a positive resist composition that is capable of forming a resist pattern having little resist pattern top loss and high contrast.

Moreover, according to the present disclosure, it is possible to provide a method of forming a resist pattern that is capable of forming a resist pattern having little resist pattern top loss and high contrast.

1. A positive resist composition comprising:
a copolymer A;
a copolymer B; and
a solvent, wherein
a difference between surface free energy of the copolymer A and surface free energy of the copolymer B is 4 mJ/m² or more.

2. The positive resist composition according to claim 1, wherein at least one of the copolymer A and the copolymer B is a main chain scission-type copolymer that includes a halogen atom.

3. The positive resist composition according to claim 2, wherein at least one of the copolymer A and the copolymer B includes a fluorine substituent, at least one of the halogen atom is a fluorine atom, and the fluorine atom is included in the fluorine substituent.

4. The positive resist composition according to claim 1, not substantially comprising a component having a weight-average molecular weight (Mw) of less than 1,000.

5. The positive resist composition according to claim 1, wherein at least one of the copolymer A and the copolymer B includes a monomer unit (V) represented by formula (V), shown below, 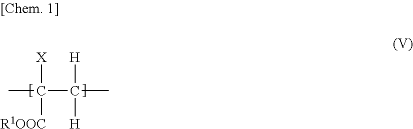
where, in formula (V), X is a halogen atom, a cyano group, an alkylsulfonyl group, an alkoxy group, a nitro group, an acyl group, an alkyl ester group, or a haloalkyl group, and R¹ is an organic group including not fewer than 3 and not more than 10 fluorine atoms.

6. The positive resist composition according to claim 1, wherein the copolymer A includes:
a monomer unit (I) represented by formula (I), shown below, 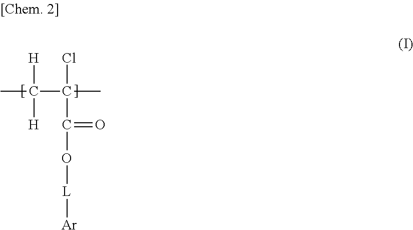
where, in formula (I), L is a divalent linking group that includes a fluorine atom, and Ar is an optionally substituted aromatic ring group; and
a monomer unit (II) represented by formula (II), shown below, 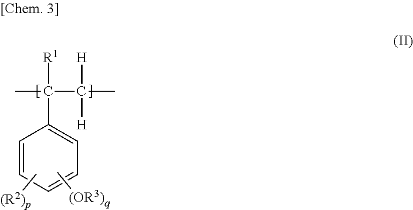
where, in formula (II), R¹ is an alkyl group, R² is a hydrogen atom, an alkyl group, a halogen atom, a haloalkyl group, a hydroxyl group, a carboxyl group, or a halogenated carboxyl group, R³ is a hydrogen atom, an unsubstituted alkyl group, or a fluorine atom-substituted alkyl group, p and q are integers of not less than 0 and not more than 5, and p+q=5.

7. The positive resist composition according to claim 1, wherein the copolymer B includes:
a monomer unit (III) represented by formula (III), shown below, 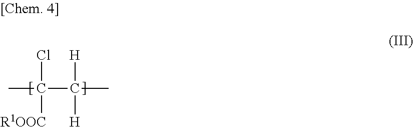
where, in formula (III), R¹ is an organic group including not fewer than 5 and not more than 7 fluorine atoms; and
a monomer unit (IV) represented by formula (IV), shown below, 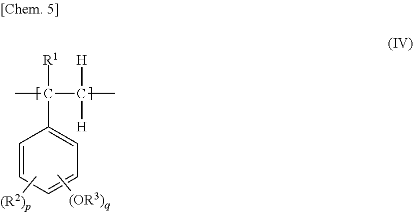
where, in formula (IV), R¹ is an alkyl group, R² is a hydrogen atom, a fluorine atom, an unsubstituted alkyl group, or a fluorine atom-substituted alkyl group, R³ is a hydrogen atom, an unsubstituted alkyl group, or a fluorine atom-substituted alkyl group, p and q are integers of not less than 0 and not more than 5, and p+q=5.

8. A method of forming a resist pattern comprising:
forming a resist film using the positive resist composition according to claim 1;
exposing the resist film; and
developing the resist film that has been exposed.

9. The method of forming a resist pattern according to claim 8, wherein the developing is performed using an alcohol.
